(19) United States
(12) Patent Application Publication
(10) Pub. No.: US 2026/0223638 A1
(43) Pub. Date: Jul. 30, 2026

(54) DYNAMIC MICRO-TRANSFER-PRINTING STAMPS

(71) Applicant: X-Celeprint Limited, Dublin (IE)

(72) Inventors: Ronald S. Cok, Rochester, NY (US); David Gomez, Holly Springs, NC (US)

(21) Appl. No.: 19/450,014

(22) Filed: Jan. 15, 2026

Related U.S. Application Data
(60) Provisional application No. 63/749,223, filed on Jan. 24, 2025.

(51) Int. Cl. H10P 72/70

(52) U.S. Cl. CPC H10P 72/7434; H10P 72/7412

(57) ABSTRACT

A micro-transfer-printing stamp includes a rigid support and one or more stamp posts comprising a visco-elastic material disposed over the rigid support. Each of the stamp posts can extend in a direction away from the rigid support to an asymmetric distal surface of the stamp post. The asymmetric distal surface can comprise a single asymmetric structure, multiple asymmetric structure, or multiple substantially similar asymmetric structures. Some asymmetric distal surfaces comprise a planar portion and one or more asymmetric micro-tips extending from the planar portion. Others can fold over when adhered to a component on a component source wafer. A contact area and adhesion between the distal surface and the component can increase when the distal surface is pressed against the component and can decrease when pressing is reduced and the stamp post relaxes when the component is removed from the component source wafer.

### PRIORITY APPLICATION

This application claims the benefit of U.S. Provisional Ser. No. 63/749,223, filed on Jan. 24, 2025, the disclosure of which is hereby incorporated by reference herein in its entirety.

### REFERENCE TO RELATED APPLICATION

The present disclosure is related to U.S. Provisional Application No. 63/619,987 entitled Stamps for Micro-Transfer-Printing with Curved Stamp Post Ends to Cok et al filed Jan. 11, 2024, whose relevant contents are incorporated herein by reference.

### TECHNICAL FIELD

The present disclosure generally relates to micro-transfer printing stamps, stamp structures, and methods of using and constructing such stamps.

### BACKGROUND

Substrates with electronically active components distributed over the extent of the substrate are used in a variety of electronic systems, for example, in flat-panel display components such as flat-panel liquid crystal or organic light emitting diode (OLED) displays, in imaging sensors, and in flat-panel solar cells. The electronically active components are typically either assembled on the substrate, for example using individually packaged surface-mount integrated-circuit components and pick-and-place tools, or by coating a layer of semiconductor material on the substrate and then photolithographically processing the semiconductor material to form thin-film circuits on the substrate. Individually packaged integrated-circuit components typically have smaller transistors with higher performance than thin-film circuits but the packages are larger than can be desired for highly integrated systems.

Methods for transferring small, active components from one substrate to another are described in U.S. Pat. Nos. 7,943,491, 8,039,847, 7,622,367. In some such approaches, small integrated circuits are formed on a native semiconductor source wafer. The small, unpackaged integrated circuits, or chiplets, are released from the native source wafer by pattern-wise etching portions of a sacrificial layer located beneath the chiplets, leaving each chiplet suspended over an etched sacrificial layer portion by a tether physically connecting the chiplet to an anchor separating the etched sacrificial layer portions. A viscoelastic stamp is pressed against the process side of the chiplets on the native source wafer, adhering each chiplet to an individual stamp post. The stamp with the adhered chiplets is removed from the native source wafer. The chiplets on the stamp posts are then pressed against a non-native target substrate or backplane with the stamp and adhered to the target substrate. Such micro-transferred components can provide the high performance of crystalline semiconductor components together with the small size of unpackaged dies.

Micro-transfer printing stamps are an important part of any micro-transfer printing system and method. Such stamps are typically constructed using a master comprising a substrate with layers of photolithographically patterned material defining the stamp structure. Typically, each stamp comprises an array of individual stamp posts and each stamp post contacts a component (e.g., a chiplet) during printing. The structure of the stamp post can affect the component pickup from a source wafer and the component printing to a target substrate. In some designs, the distal end of each individual stamp post is flat. In other designs, the distal end of each individual stamp post is structured. For example, U.S. Pat. No. 9,412,727 discloses a stamp with micro-tips in a three-dimensional relief pattern. There is an ongoing need, therefore, for stamps, stamp structures, and methods of using and constructing a stamp that are relatively low cost, are highly reliable, and are easy-to-use for a variety of component micro-transfer printing processes.

### SUMMARY

The present disclosure provides, inter alia, structures and methods for constructing stamps having improved performance, for example using lower-cost or more efficient construction methods and designs, and for more efficiently micro-transfer-printing components (e.g., devices) from a component (or device) source wafer to a target substrate with the stamp with improved yields.

According to embodiments of the present disclosure, a micro-transfer-printing stamp can comprise a rigid support and a stamp post disposed on or over the rigid support. The stamp post can be in direct contact with the rigid support or can be disposed on and in direct contact with a layer that is between the stamp post and the rigid substrate, for example a mesa in direct contact with the rigid support. The stamp post can extend in a direction away from the rigid support to a non-planar asymmetric distal surface of the stamp post. The stamp post can be operable to contact a component surface of a component (e.g., an exposed side of the component) when the stamp post is pressed against the component surface, thereby defining and forming a contact area having a contact-area perimeter within which the asymmetric distal surface continuously contacts the surface. In embodiments, all of the contact area within the contact-area perimeter is in contact with the component surface. The stamp post can comprise a visco-elastic material.

In some embodiments, the asymmetric distal surface can comprise multiple planar sidewalls that extend away from the rigid support and at the distal end of the sidewalls form a perimeter comprising line segments, curves, or a combination of line segments and curves surrounding the asymmetric distal surface.

In some embodiments, the asymmetric distal surface comprises a single asymmetric structure. In some embodiments, the asymmetric distal surface comprises multiple asymmetric structures. The multiple asymmetric structures can be different asymmetric structures or can be substantially similar asymmetric structures, or some different and some similar. In some embodiments, the asymmetric distal surface can comprise a planar portion and one or more micro-tip portions, the planar portion can be planar, and the one or more micro-tip portions can each comprise an asymmetric micro-tip extending from the planar portion of the asymmetric distal surface.

In some embodiments, a proximal end of the stamp post can be in direct contact with the rigid support. Some embodiments can comprise a single mesa disposed on and in direct contact with the rigid support and a proximal end of the stamp post can be on and in direct contact with the mesa.

In some embodiments, the stamp post comprises PDMS.

According to embodiments of the present disclosure, a one-dimensional or a two-dimensional array of stamp posts are disposed over the rigid support. Each of the stamp posts can extend in a direction away from the rigid support to an asymmetric distal surface of the stamp post. Each of the stamp posts can comprise a visco-elastic material such as PDMS. In embodiments, a proximal end of each of the stamp posts is in direct contact with the rigid support. Some embodiments can comprise a single mesa disposed on and in direct contact with the rigid support and a proximal end of each of the stamp posts is on and in direct contact with the single mesa. Some embodiments can comprise multiple mesas each on and in direct contact with the rigid support and a proximal end of more than one stamp post is on and in direct contact with each of the separate mesas and extend away from the rigid support to an asymmetric distal stamp post end. Some embodiments can comprise a separate mesa for each of the stamp posts. The separate mesas can each be on and in direct contact with the rigid support. A proximal end of only a single stamp post is on and in direct contact with each of the separate mesas so that each of multiple mesas disposed on and in direct contact with the rigid support supports a single stamp post disposed on and in direct contact with the mesa that extends away from the rigid support to an asymmetric distal surface of the stamp post.

According to embodiments of the present disclosure, a line projected through a point or surface of the distal end of the asymmetric distal surface farthest from and orthogonal to the rigid support does not intersect any other portion of the asymmetric distal surface. In some embodiments, a line projected through a point or surface of the distal end of the asymmetric distal surface farthest from and orthogonal to the rigid support can intersect another portion of the asymmetric distal surface.

According to embodiments, each of the stamp posts in the array can be in contact with a neighboring stamp post in one or two dimensions.

In embodiments, the asymmetric distal surface has multiple different surface portions that have different shapes. In embodiments, at least some different ones of the different shapes can be any one or combination of planar and polygonal, nonplanar and curved, nonplanar and convex, or nonplanar and concave. In some embodiments, at least one of the different surface portions is convex and another one of the different surface portions is concave and the convex and the concave surface portions meet at a point or line that is farthest from the rigid support. In some embodiments, the asymmetric distal surface in contact under first pressure with a component has a first contact area. In some embodiments, the asymmetric distal surface in contact under second pressure with a component has a second contact area. In some embodiments, the first pressure is greater than the second pressure and the first contact area is greater than the second contact area. In embodiments of the present disclosure, the asymmetric distal surface can be convex in a direction orthogonal to a surface of the target substrate or rigid substrate on or over which the stamp post is disposed. In embodiments of the present disclosure, the asymmetric distal surface can be concave in a direction orthogonal to a surface of the target substrate or rigid substrate on or over which the stamp post is disposed. In some embodiments, the asymmetric distal surface can comprise continuous surface portions having two or more different areas.

According to embodiments of the present disclosure, a method of transfer printing a component from a component source wafer to a target substrate can comprise (i) providing the component source wafer comprising the component suspended over the component source wafer with a tether connecting the component to an anchor portion of the component source wafer, (ii) providing the target substrate, and (iii) providing a micro-transfer-printing stamp comprising a stamp post having an asymmetric distal surface at a distal end of the stamp post. Using a micro-transfer printer to move the micro-transfer-printing stamp, the asymmetric distal surface of the stamp post can be pressed against the component with a first pressure to adhere the component to the asymmetric distal surface over a first continuous contact area. The component can be removed from the component source wafer with the micro-transfer-printing stamp under the control of the micro-transfer printer and pressed against or to the target substrate with a second pressure less than the first pressure to adhere the component to the target substrate over a second continuous contact area. the micro-transfer printer can then remove the micro-transfer-printing stamp from the target substrate, leaving the component adhered to the target substrate. The first continuous contact area can be greater than the second continuous contact area. The first and second contact areas can each have a contact-area perimeter surrounding the respective contact areas and the entire area of the distal end of the stamp post within the contact-area perimeter of the asymmetric distal surface can be in contact with the component when pressed against the component with the first or second pressure.

In some embodiments, the component is disposed on a surface of the component source wafer and methods can comprise moving the stamp post in a horizontal shear direction with respect to the surface (e.g., substantially or at least partially parallel to the surface) when the asymmetric distal surface of the stamp post is pressed against the component. The movement in the horizontal shear direction can be less than an extent of the component in the horizontal direction. The horizontal shear direction can be in a direction (i) from a concave surface to a convex surface of the asymmetric distal surface, (ii) from a surface less parallel (e.g., closer to orthogonal) to a surface of the rigid support from which the stamp post extends to a surface more parallel (e.g., farther from orthogonal) to the surface, (iii) from a center of the stamp post to the point of the stamp post farthest from the rigid support, or (iv) any useful combination of these. In some embodiments, the rigid support can have a rigid-substrate surface on which the stamp post is disposed. In some embodiments, the asymmetric distal surface can comprise an asymmetric structure comprising a planar surface having a normal projecting in a direction that is non-orthogonal to the rigid-substrate surface. In some embodiments, the horizontal direction is substantially in a plane with the normal and partially opposite a direction of the normal. The movement in the horizontal direction can increase a contact area of the asymmetric distal surface in contact with the component. The component can be pressed directly onto the target substrate. The asymmetric distal surface can comprise multiple different continuous surface portions. A larger continuous surface portion can have a larger area, and a smaller continuous surface portion can have a smaller area smaller than the larger area. The larger area can be a largest area larger than an area of any others of the multiple different continuous surface portions.

According to embodiments of the present disclosure, a method of transfer printing a component from a component source wafer to a target substrate can comprise providing (i) the component source wafer comprising the component disposed over or on a surface of the component source wafer, (ii) the target substrate, and (iii) a micro-transfer-printing stamp. A micro-transfer printer can press a stamp post of the stamp against the component and move the stamp in a direction parallel to the surface, remove the component from the component source wafer with the micro-transfer-printing stamp, press the component adhered to the asymmetric distal surface of the stamp post to the target substrate, and remove the micro-transfer-printing stamp from the target substrate leaving the component adhered to the target substrate. Some embodiments can comprise moving the stamp in a direction parallel to the surface using the transfer printer. The direction parallel to the surface when removing the component from the component source wafer can be at least partially opposite to the direction parallel to the surface when pressing the component to the target substrate.

Some embodiments can comprise moving the stamp away from the target substrate at the same time as moving the stamp in a direction parallel to the surface using the micro-transfer printer. In some embodiments, the stamp post has sides and a center equidistant from multiple ones of the sides, a line projected through a point or surface of the distal end of the asymmetric distal surface farthest from the rigid support orthogonal to a surface of the rigid support does not intersect the center in at least one dimension, and the direction parallel to the surface is at least partially a direction from the point toward the center. In some embodiments, the asymmetric distal surface has a surface portion that is a concave continuous surface portion and a surface portion that is a convex continuous surface portion and the direction parallel to the surface is at least partially a direction from the convex surface to the concave surface. In some embodiments, the asymmetric distal surface comprises continuous surface portions, a largest continuous surface portion has a largest area larger than an area any of the other continuous surface portions over the target substrate, a smaller continuous surface portion of the continuous surface portions has a smaller area over the target substrate smaller than the largest area, and methods of the present disclosure can comprise moving the stamp post from an edge of the stamp post toward the largest continuous surface portion.

According to embodiments of the present disclosure, a method of picking a component from a component source wafer with a stamp using a micro-transfer printer can comprise providing the component source wafer, the stamp, and the transfer printer, pressing a distal surface of a stamp post of the stamp against the component with the transfer printer so that at least some portion of the stamp post folds over to adhere the component to the distal surface, and removing the component adhered to the stamp from the component source wafer with the transfer printer.

According to embodiments of the present disclosure, a micro-transfer-printing stamp can comprise a rigid support and a visco-elastic stamp post disposed directly on and in physical contact with and extending away from the rigid support so that each stamp post is in direct contact with the rigid support, for example no mesa or other stamp-material structure (e.g., a mesa) is disposed between a proximal portion of the stamp post adjacent to the rigid support and the rigid support.

According to embodiments of the present disclosure, a micro-transfer-printing stamp can comprise a rigid support, a visco-elastic mesa disposed on the rigid support, and a single visco-elastic stamp post disposed directly on the mesa and extending away from the rigid support.

According to embodiments of the present disclosure, a micro-transfer-printing stamp can comprise a rigid support, a plurality of visco-elastic mesas disposed on the rigid support, and a single visco-elastic stamp post disposed directly on each of the mesas and extending away from the rigid support. Each of the single visco-elastic stamp posts can be disposed directly over the center of the mesa on which the single visco-elastic stamp post is directly disposed. A center of each of the single visco-elastic stamp posts can be disposed directly over the center of the mesa on which the single visco-elastic stamp post is directly disposed.

According to embodiments of the present disclosure, a micro-transfer-printing stamp can comprise a rigid support and a stamp post disposed over the rigid support. The stamp post can extend in a direction away from the rigid support to an asymmetric distal surface of the stamp post. The stamp post can comprise a visco-elastic material. The asymmetric distal surface can be at least partially non-planar. The asymmetric distal surface can be a portion of the stamp post operable to contact a component surface over a contact area having a contact-area perimeter when the stamp post is pressed against the surface. The portion of the stamp post can continuously contact the component surface when the stamp post is pressed against the component surface. The portion of the stamp post can be free of holes so that all of the area within the contact-area perimeter is in contact with the component surface.

The asymmetric distal surface can extend asymmetrically away from the rigid support. The asymmetric distal surface can have a substantially rectangular perimeter and the asymmetric distal surface can be asymmetric with respect to and can be a non-mirror image (e.g., not a mirror image) on either side of (i) a plane orthogonal to a surface of the rigid substrate, (ii) a plane parallel to a flat side of the stamp post, or (iii) any plane orthogonal to a surface of the rigid substrate extending through a center of the stamp post contacting or over the rigid support. In embodiments, a portion or point of the asymmetric distal surface farthest from the rigid substrate is disposed within a perimeter of asymmetric distal surface and the portion or point is not at or in contact with a stamp post edge or stamp post sidewall.

According to embodiments of the present disclosure, a micro-transfer-printing stamp comprises a rigid support and a post or an array of posts disposed over the rigid support (e.g., and directly on the rigid support or with a mesa disposed therebetween). Each of the posts in the array of posts can extend in a direction away from the rigid support to a distal surface of the post (e.g., in a direction orthogonal to a target-substrate surface of the target substrate on or over which the posts are disposed). In some embodiments, the distal surface of each post in the array of posts is substantially convex with a non-central portion farther from the rigid support than another portion of the distal surface so that the distal end of the post is asymmetric in at least one dimension, forming an asymmetric distal surface. The asymmetric distal surface can be structured to contact a component (e.g., a device, structure, or material) when the asymmetric distal surface is pressed against the component. In some embodiments, the distal surface of each post in the array of posts is substantially concave with a non-central portion closer to the rigid support than another portion of the asymmetric distal surface. The concave surface can be structured to contact a component (e.g., device) when the distal surface is pressed against the component.

In some embodiments, the posts in the array of posts can comprise an elastomeric or visco-elastic material. In some embodiments, the posts in the array of posts can comprise PDMS. In some embodiments, the asymmetric distal surface of each of the posts is continuously curved or comprises portions of one or more different planes.

In some embodiments, a portion of the asymmetric distal surface is flat. In some embodiments, the portion that is flat forms a perimeter around an asymmetric structure within the perimeter, at a center of the asymmetric distal surface, or around each of multiple asymmetric structures on the asymmetric distal surface.

According to some embodiments of the present disclosure, a micro-transfer-printing stamp comprises a mesa disposed on the rigid support between the rigid support and the stamp posts, and the stamp posts extend from the mesa in a direction away from the rigid support. In some embodiments, the stamp comprises multiple, separate and independent mesas and one or more stamp posts extend from each mesa. In some embodiments, only one stamp post extends from each mesa, for example from a center of the mesa.

In some embodiments of the present disclosure, a component having a component surface is in contact with the asymmetric distal surface of a post (e.g., one of the stamp posts), the post is under compression, and all of the asymmetric distal surface is in contact with the component surface. In some embodiments of the present disclosure, a component having a component surface is in contact with the asymmetric distal surface of a post (e.g., one of the stamp posts), the post is under compression, and less than all of the asymmetric distal surface is in contact with the component surface. Some embodiments comprise a component source wafer and the component is physically connected to the component source wafer, for example with a tether connected to an anchor portion of the component source wafer.

Some embodiments comprise a target substrate having a target substrate surface and the component is in contact with the target substrate surface on a surface of the component opposite the component surface in contact with the stamp, e.g., when micro-transfer printing the component to the target substrate. The component can comprise a fractured or separated tether as a consequence of micro-transfer printing the component from a component source wafer to a target substrate. The tether can comprise an organic or inorganic material and can comprise a dielectric.

According to some embodiments, the asymmetric distal surface of the stamp post is concave or convex in one dimension. According to some embodiments, the distal surface of the stamp post is concave or convex in two dimensions. According to some embodiments, the asymmetric distal surface of the stamp post is asymmetric in one dimension or direction. According to some embodiments, the distal surface of the stamp post is asymmetric in two dimensions or directions.

According to some embodiments, a method of assembling a component can comprise providing a component source substrate with a component having a component surface connected to the component source substrate, providing a micro-transfer-printing stamp, pressing a post of the stamp against the component surface with the transfer printer so that the component is adhered to a first contact area of the asymmetric distal surface, removing the component from the component source substrate by moving the stamp away from the component source substrate with the transfer printer, relaxing the compressed post so that the component is adhered to the post with a second contact area of the asymmetric distal surface less than the first contact area, transporting the stamp and component to a target substrate having a target substrate surface with the transfer printer, and pressing the component against the target substrate surface with the printer so that the component is adhered to the target substrate surface and the component is adhered to the post with a third contact area of the asymmetric distal surface smaller than the first contact area with the transfer printer. The third contact area can be no smaller than or greater than the second contact area and can be smaller than the first contact area. Some methods of the present disclosure comprise removing the stamp post from the component, for example removing the stamp from the target substrate.

In some embodiments, a method of making a micro-transfer-printing stamp mold can comprise providing a base, coating the base with a curable material (e.g., a polymer, such as an acrylic), pattern-wise curing the curable material to form a patterned structure (e.g., a mold pattern) comprising a cured material, wherein the patterned structure comprises one or more periodically spaced features each with an asymmetric distal end such as a one-dimensionally asymmetric distal end or a two-dimensionally asymmetric distal end, and removing any uncured curable material to form a stamp mold. Further embodiments can comprise coating the stamp mold with an uncured curable stamp material (e.g., PDMS), curing the stamp material, and removing the stamp from the stamp mold. Some embodiments further comprise contacting a printable component on a component source wafer with the stamp, removing the component from the component source wafer, transporting the removed component to a target substrate, and printing the component onto the target substrate.

In some embodiments, a method of making a micro-transfer-printing stamp mold, comprises providing a base, coating the base with a curable material (e.g., a polymer, such as an acrylic), and forming a patterned structure (e.g., a mold pattern) comprising a cured material from the curable material. The patterned structure can comprise one or more periodically spaced features each with an asymmetric end (e.g., a one-dimensionally asymmetric end or a two-dimensionally asymmetric end). The method can comprise removing any uncured curable material to form a stamp mold. In some embodiments, the method comprises treating or coating a surface of the patterned structure in order to reduce adhesion to a stamp during stamp fabrication (e.g., comprising fluorinating the surface). In some embodiments, the method comprises 3D-printing the patterned structure. In some embodiments, the method comprises using two-photon polymerization to form the patterned structure. In some embodiments, the method comprises pattern-wise curing the curable material to form the patterned structure. The asymmetric end can contact the base. In some embodiments, the asymmetric end does not contact the base. The curable material can have a cure temperature that is higher than a cure temperature of a curable stamp material for the stamp (e.g., PDMS). The curable material can have a cure temperature that is higher than a cure temperature of PDMS. Some embodiments can comprise coating the stamp mold with an uncured curable stamp material (e.g., PDMS), curing the stamp material, and removing the stamp from the stamp mold. The curable material can have a cure temperature that is higher than a cure temperature of the curable stamp material.

In some embodiments, a micro-transfer-printing stamp mold can comprise a cured polymer defining a patterned structure, (e.g., a cured acrylic polymer) with the patterned structure comprising periodically spaced features each with an asymmetric end. The features can correspond to stamp posts of the stamp. The features can have one-dimensional asymmetry. The features can have two-dimensional asymmetry. The patterned structure can be treated or coated to reduce adhesion (e.g., can be fluorinated). The patterned structure can have a higher cure temperature than a cure temperature of a curable material (e.g., a PDMS) for the stamp. The patterned structure can have a higher cure temperature than a cure temperature of PDMS.

According to embodiments of the present disclosure, a micro-transfer-printing stamp can comprise a rigid support and a stamp post disposed over the rigid support. The stamp post can extend in a direction away from the rigid support to a distal surface of the stamp post and can be operable to contact a component surface when the stamp post is pressed against the component surface, thereby defining a contact area having a perimeter within which the distal surface continuously contacts the surface. The stamp post can comprise a visco-elastic material. The distal surface can comprise a planar portion and one or more micro-tip portions that each comprise an asymmetric micro-tip extending from the planar portion.

Structures and methods described herein enable stamp structures and a release and printing process for micro-transfer printing components from a source wafer to a target substrate having improved yields and reliability.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1 is a perspective of a stamp with spatially separated posts with a detail and cross-section of a post having an asymmetric distal surface disposed on a rigid support according to illustrative embodiments of the present disclosure;

FIG. 2 is a perspective of a stamp with spatially separated posts having an asymmetric distal surface disposed on a mesa disposed on a rigid support according to illustrative embodiments of the present disclosure;

FIG. 3 is a perspective of a stamp with contacting posts having an asymmetric distal surface disposed on a rigid support according to illustrative embodiments of the present disclosure;

FIG. 4 is a perspective of a stamp with contacting posts having an asymmetric distal surface that is asymmetric in one dimension with a post detail and projection with hidden lines according to illustrative embodiments of the present disclosure;

FIG. 5A is a perspective of separated posts having an asymmetric distal surface with no sidewalls disposed on a rigid support according to illustrative embodiments of the present disclosure;

FIG. 5B is a perspective of separated posts having an asymmetric distal surface with no sidewalls disposed on a mesa on a rigid support according to illustrative embodiments of the present disclosure;

FIG. 6A is a perspective of a stamp comprising multiple contacting stamp posts having an asymmetric distal surface and no sidewalls over a portion of a surface of a rigid support according to illustrative embodiments of the present disclosure;

FIG. 6B is a perspective of a stamp comprising contacting stamp posts having an asymmetric distal surface with no sidewalls over an entire surface of a rigid support or mesa according to illustrative embodiments of the present disclosure;

FIG. 6C is a perspective of a stamp post having an asymmetric distal surface with multiple asymmetric structures over an entire asymmetric distal surface of a stamp post with sidewalls according to illustrative embodiments of the present disclosure;

FIG. 7 is a perspective of a stamp with separated posts each having an asymmetric distal surface and disposed on a separate mesa disposed on a rigid support with a post detail according to illustrative embodiments of the present disclosure;

FIGS. 8A-8F are successive cross sections of a stamp having an asymmetric distal surface transfer picking a component from a component source wafer and printing the component to a target substrate with different contact areas according to illustrative embodiments of the present disclosure;

FIG. 9A is a cross section of a stamp post having an asymmetric distal surface comprising a convex continuous curved surface and a concave continuous curved surface and a top that is not over the stamp post according to illustrative embodiments of the present disclosure;

FIG. 9B is a cross section of a stamp post having an asymmetric distal surface comprising a convex continuous curved surface and a concave continuous curved surface and a top that is over the stamp post according to illustrative embodiments of the present disclosure;

FIG. 9C is a cross section of a stamp post having an asymmetric distal surface comprising a continuous planar surface and a concave continuous curved surface and a top that is over the stamp post according to illustrative embodiments of the present disclosure;

FIG. 9D is a cross section of a stamp post having an asymmetric distal surface comprising continuous planar surfaces and top that is not over the stamp post according to illustrative embodiments of the present disclosure;

FIG. 9E is a cross section of a stamp post having an asymmetric distal surface comprising a continuous convex surface and sidewalls in a direction orthogonal to rigid support according to illustrative embodiments of the present disclosure;

FIG. 9F is a cross section of a stamp post having an asymmetric distal surface comprising a continuous concave surface and sidewalls in a direction orthogonal to rigid support according to illustrative embodiments of the present disclosure;

FIG. 9G is a cross section of a stamp comprising separated stamp posts of FIG. 8A disposed on a substrate according to illustrative embodiments of the present disclosure;

FIG. 9H is a cross section of a stamp comprising contacting stamp posts of FIG. 8A disposed on a substrate according to illustrative embodiments of the present disclosure;

FIGS. 10A-10H are successive cross sections of a stamp having an asymmetric distal surface transfer picking a component from a component source wafer and printing the component to a target substrate according to illustrative embodiments of the present disclosure;

FIG. 11 is a flow diagram of methods according to illustrative embodiments of the present disclosure;

FIG. 12 is a flow diagram of methods according to illustrative embodiments of the present disclosure; and

FIG. 13 is a cross section of a stamp in horizontal motion contacting a component disposed on a target substrate according to illustrative embodiments of the present disclosure.

Features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The figures are not drawn to scale since the variation in size of various elements in the Figures is too great to permit depiction to scale.

### DETAILED DESCRIPTION OF CERTAIN EMBODIMENTS

The present disclosure provides, inter alia, structures and methods for micro-transfer printing components (e.g., devices) from a component (or device) source substrate (or source wafer) to a target substrate (or target wafer or destination substrate). Embodiments of the present disclosure provide stamps that can pick up components from the component source wafer and print the components to the target substrate with improved yields for a greater variety of components under a greater variety of process, source wafer, target substrate, and material conditions.

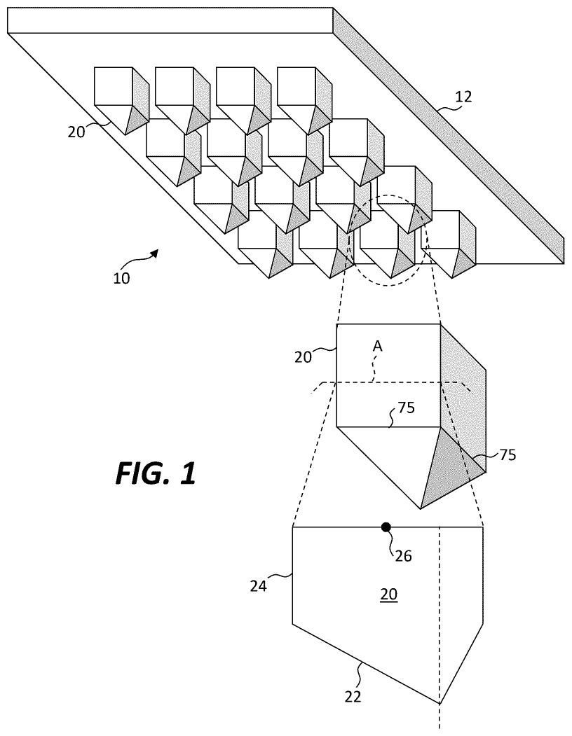

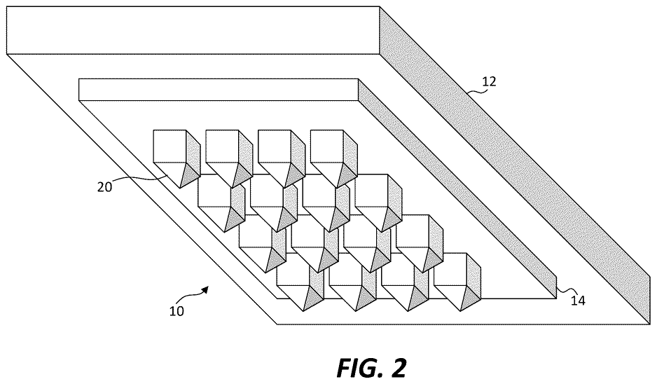

According to some embodiments of the present disclosure and as shown in FIGS. 1 and 2, a micro-transfer-printing stamp 10 can comprise a rigid support 12 (e.g., a rigid substrate) and an array of stamp posts 20 disposed over rigid support 12 (e.g., and directly on rigid support 12 as shown in FIG. 1 or with a mesa 14 disposed therebetween as shown in FIG. 2). Each stamp post 20 can comprise an elastic material, e.g., a visco-elastic or elastomeric material, such as polydimethylsiloxane (PDMS), having rate-dependent adhesion. Each of stamp posts 20 in the array of stamp posts 20 can extend in a direction away from rigid support 12 (e.g., substantially orthogonally) to a distal surface 22 (a distal end 22 of stamp posts 20). Distal end 22 is at an opposite end of a proximal end of stamp post 20 disposed adjacent to, over, above, or in contact with rigid support 12 or a mesa 14 on rigid support 12. Distal end 22 can have an asymmetric distal surface 22. (Distal end 22 and asymmetric distal surface 22 of distal end 22 are not generally distinguished herein). Each asymmetric distal surface 22 can have one or more asymmetric structures that are in contact with each other or are separated from each other on asymmetric distal surface 22 of stamp post 20.

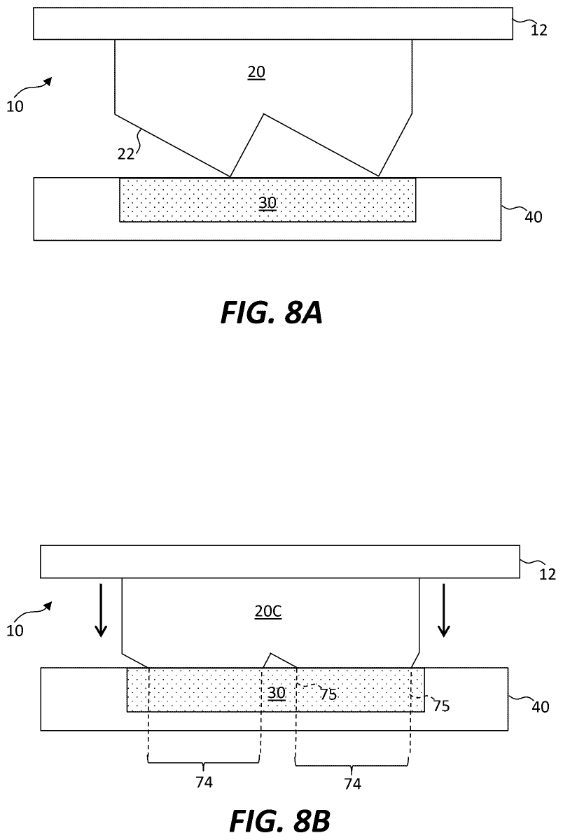

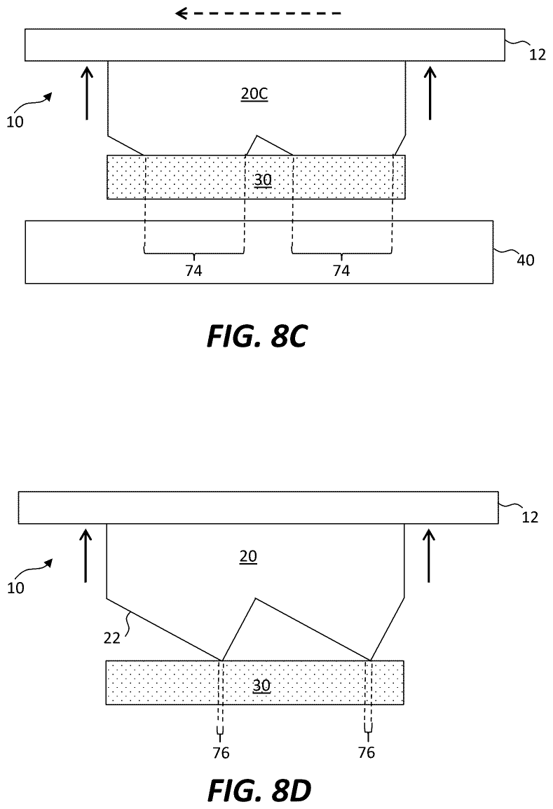

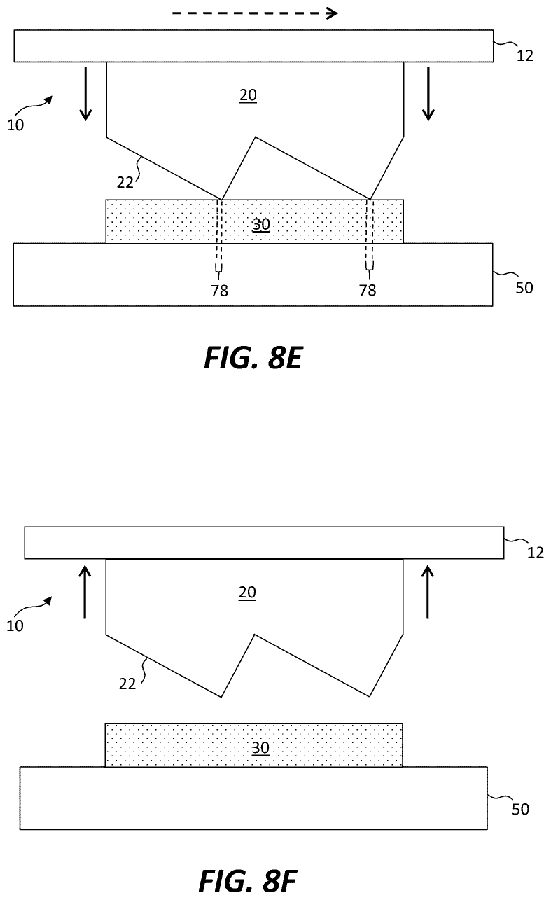

Asymmetric distal surface 22 can be a portion of stamp post 20 operable to contact a surface, e.g., a component 30 (see FIGS. 8A-8F), when stamp post 20 is pressed against the surface. The portion of stamp post 20 (e.g., of asymmetric distal surface 22) in contact with the surface can be a contact area and the contact area can continuously contact, or be in continuous contact with, the surface (e.g., a surface of component 30) when stamp post 20 is pressed against the surface. For example, the portion of asymmetric distal surface 22 (the contact area) can be completely continuous and free of any holes extending from the asymmetric distal surface 22 toward the rigid substrate 12. A perimeter or all edges of the contact area or distal surface 22 can form a simple closed curve, for example is not a ring and the interior of the perimeter (e.g., asymmetric distal surface 22) can be continuous (e.g., without holes) and can continuously contact the surface when stamp post 20 is pressed against the surface so that all of the area within the perimeter is in contact with the surface of component 30.

In embodiments, asymmetric distal surface 22 is non-planar or non-planar compared to a plane parallel to a surface of rigid support 12 on which stamp posts 20 are disposed or mesa 14 is disposed. In embodiments, asymmetric distal surface 22 can extend away from rigid support 12 so that some portions of asymmetric distal surface 22 are farther away from rigid support 12 than other portions of asymmetric distal surface 22, but the portions can be continuous. In embodiments, stamp posts 20 can have vertical sides or sidewalls 24 that extend substantially orthogonally to the surface of rigid support 12 whose distal ends 22 form a perimeter around asymmetric distal surface 22. In embodiments, stamp post 20 can be rectangular and asymmetric distal surface 22 can be asymmetric with respect to (e.g., is not a mirror image on either side of) a plane parallel to a post side 24 or one or more or any plane orthogonal to a surface of rigid substrate 12 extending through a center 26 of stamp post 20, e.g., a center 26 of stamp post 20 in contact with rigid support 12 or mesa 14 or center 26 of a cross section of stamp post 20 in a plane parallel to a surface of rigid support 12 on or over which stamp post 20 is disposed. Center 26 of stamp post 20 can be equidistant from sidewalls 24 or equidistant from opposing sidewalls 24. In embodiments, the portion(s) or point(s) of asymmetric distal surface 22 farthest from rigid substrate 12 is disposed within a perimeter of asymmetric distal surface 22, e.g., defined by the distal ends of sidewalls 24 and is not at or in contact with a stamp post edge 24 or sidewall 24 of stamp post 20.

In embodiments, mesa 14 can be a bulk layer or pedestal disposed on (e.g., disposed directly on) rigid support 12 and stamp posts 20 can be disposed on (e.g., disposed directly on) mesa 14 with a proximal end of stamp posts 20 in direct contact with mesa 14 and distal end 22 of stamp posts 20 on an opposite end of stamp posts 20 from the proximal end. In embodiments, stamp posts 20 (and optionally mesa 14) are flexible and elastic so that they can be deformed by pressure without breaking and can return to their original shape when the pressure is removed. Stamp posts 20 (and optionally mesa 14) can be more flexible than rigid support 12. Distal surface 22 can be that portion of stamp post 20 structured to contact a surface of a component 30 when stamp post 20 is pressed against component 30. In some embodiments, stamp post 20 is pressed against component 30 without stamp post 20 collapse (e.g., without stamp post 20 bending although stamp post 20 can bulge outward away from center 26 of stamp post 20 in a direction parallel to a surface of rigid support 12 from which stamp post 20 extends when compressed). In some embodiments, stamp post 20 is pressed against component 30 so that stamp post 20 bends or folds (e.g., bends or folds over so that at least a portion of stamp post 20 over rigid support 12 is not over another different portion of stamp post 20). In some embodiments, each component 30 being printed contacts only one stamp post 20 and only one distal end 22. Distal end 22 can comprise one or multiple asymmetric structures and can be an asymmetric distal surface 22. Not every stamp post 20 need pick up or need print a component 30 during a print operation but can. FIGS. 1 and 2 illustrate stamp posts 20 each having an asymmetric distal surface 22 comprising a single asymmetric structure.

In some embodiments and as shown in FIGS. 1 and 2, each stamp post 20 can comprise sidewalls 24 that extend substantially orthogonally to a surface of rigid support 12 or mesa 14 from which stamp posts 20 extend or project (so that sidewalls 24 do not contact components 30 during micro-transfer printing components 30 with stamp posts 20). Distal surface 22 of each stamp post 20 in the array of stamp posts 20 can have an asymmetric distal surface 22 and can be substantially convex or have a substantially convex shape so that portions of asymmetric distal surface 22 closer to center 26 of stamp post 20 are farther from rigid support 12 than from a stamp post side 24 (e.g., sidewall(s) 24 or stamp post edge 24) of stamp post 20. The convex distal surface 22 shape can comprise multiple continuous surfaces that can be planar, at least partially curved, or entirely curved. Convex surface 70 can be structured to contact a component 30 when distal surface 22 of stamp post 20 is pressed against component 30 so that at least a portion of stamp post 20 is compressed, e.g., portions closer to center 26. A central portion of distal surface 22 can be compressed more than portions of stamp distal surface 22 that are not at center 26 of distal surface 22, e.g., compressed more than a perimeter portion of distal surface 22 closer to sidewall(s) 24 than to center 26.

In some embodiments (not shown), each stamp post 20 can comprise sidewalls 24 the extend substantially orthogonally to a surface of rigid support 12 or mesa 14 from which stamp posts 20 extend or project. Distal surface 22 of each stamp post 20 in the array of stamp posts 20 can have an asymmetric distal surface 22 and can be substantially concave or have a substantially concave shape so that portions of asymmetric distal surface 22 closer to center 26 of stamp post 20 are closer to rigid support 12 than to a stamp post side 24 (e.g., sidewall(s) 24 or stamp post edge 24) of stamp post 20. The convex distal surface 22 shape can comprise multiple continuous surfaces that can be planar, at least partially curved, or entirely curved. The concave surface 72 can be structured to contact a component 30 when distal surface 22 of stamp post 20 is pressed against component 30 so that at least a portion of stamp post 20 is compressed, e.g., portions farther from center 26. A central portion of distal surface 22 can be compressed less than portions of stamp distal surface 22 that are not at center 26 of distal surface 22, e.g., compressed less than a perimeter portion of distal surface 22 closer to sidewall(s) 24 than to center 26.

In some embodiments of the present disclosure, sidewalls 24 of stamp post 20 that have a vertical surface orthogonal to a surface of rigid support 12 from which mesa 14 or stamp posts 20 extend are not on distal end 22 of stamp post 20 and are not a portion of distal surface 22. For example, distal surface 22 can end where sidewalls 24 of stamp post 20 begin, e.g., at a perimeter of stamp post 20 asymmetric distal surface 22.

Stamps 10 can comprise multiple stamp posts 20. Stamp posts 20 can have a variety of aspect ratios, shapes, and sizes (e.g., can vary in area or cross section parallel to a surface on rigid support 12 or mesa 14 from which stamp posts 20 extend). Stamp posts 20 can have a square, rectangular, circular, or oval distal surface 22 taken as a cross section parallel to a surface of rigid support 12 over which stamp posts 20 are disposed. Stamp posts 20 can have different distributions or spacing over the extent of stamp 10, e.g., over the extent of mesa 14 or rigid support 12. Stamp posts 20 can have a variety of lengths (distance extended from mesa 14 or rigid support 12). Stamp posts 20 in a stamp 10 can be all substantially identical or can vary in size or shape. In some embodiments, stamp posts 20 can have a distal surface 22 that has a smaller area than a proximal surface closer to rigid support 12. A choice of the number of stamp posts 20 with different heights, aspect ratios, and shapes can be a matter of design choice, for example dependent on the size, shape, surface, and material composition of component 30 and the surface and material composition of any target substrate 50 to which components 30 are micro-transfer printed. The array of stamp posts 20 can be of any useful size, spacing, and arrangement on or over rigid support 12. Stamp posts 20 are typically disposed in spatial alignment with a corresponding array of components 30 on a component source wafer 40. Each stamp post 20 can be operable to contact a single component 30 so that each component 30 can adhere to distal surface 22 of stamp post 20.

Rigid support 12 can be any rigid substrate, for example comprising effectively transparent glass, that provides a stable support for mesa 14 and stamp posts 20. A transparent rigid support 12 can enable alignment using optical measurements through rigid support 12. Stamp posts 20 can comprise visco-elastic materials that exhibit rate-dependent adhesion so that, when in contact with the surface of a component 30 relatively rapid motion away from the component surface provides relatively strong adhesion between the visco-elastic stamp material and the component surface and relatively slow motion away from the component surface provides relatively weak adhesion between the visco-elastic stamp material and the component surface. Mesa 14 can comprise a same stamp material as stamp posts 20 or can comprise a different stamp material. In some embodiments, mesa 14 comprises the same stamp materials as stamp posts 20 but in different concentrations and can have a different Young's modulus than stamp posts 20. Mesa 14 and stamp posts 20 can be cast as a liquid stamp material on or in a mold in contact with rigid support 12 and then cured and removed from the mold to make stamp 10. The mold can be made using photolithographic methods and materials, for example photolithographic processing of a wafer of silicon, or 3D printing as discussed further below.

As shown in FIGS. 1 and 2, stamp posts 20 extend away from rigid support 12 to an asymmetric distal end 22. Stamp posts 20 can comprise sidewalls 24, for example sides of stamp post 20 that are orthogonal to a surface of rigid support 12 from which stamp posts 20 extend. Stamp posts 20 can comprise multiple sidewalls 24, for example four sidewalls 24 forming a square, rectangle, or quadrilateral in a cross section parallel to the surface of rigid support 12 not at distal end 22. However, in embodiments of the present disclosure, stamp post 20 can have any integer number of sidewalls 24. Sidewalls 24 can be stamp post sides 24 or stamp post edges 24 and can be portions of a plane so that one or more sidewalls 24 are planar, as shown in FIGS. 1 and 2. In some embodiments, sidewall(s) 24 can be curved, for example a cross section of stamp post 20 can be a circle or an oval or a combination of curves and planar portions. In embodiments, stamp post 20 has an asymmetric distal surface 22 regardless of sidewalls 24 of stamp post 20. In some embodiments, stamp posts 20 do not have sidewalls 24 and asymmetric distal surface 22 is in contact (e.g., direct contact) with rigid support 12 or mesa 14. In either case, in embodiments a proximal end of stamp post 20 can be in contact (e.g., in direct contact) with rigid support 12 or mesa 14. In embodiments, sidewalls 24 do not contact component 30 when picking from a component source wafer 40 or printing component 30 to a target substrate 50 (as shown in FIGS. 8A-8F).

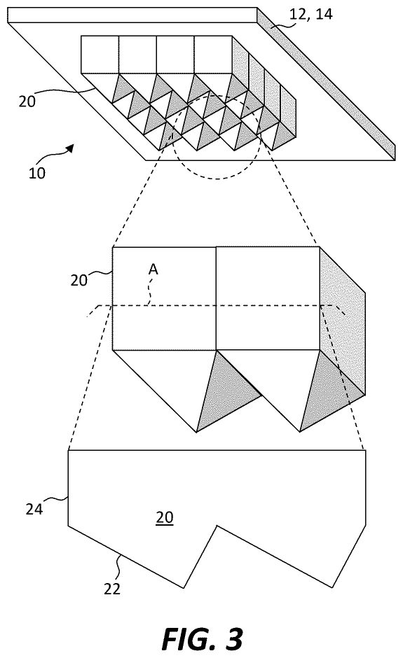

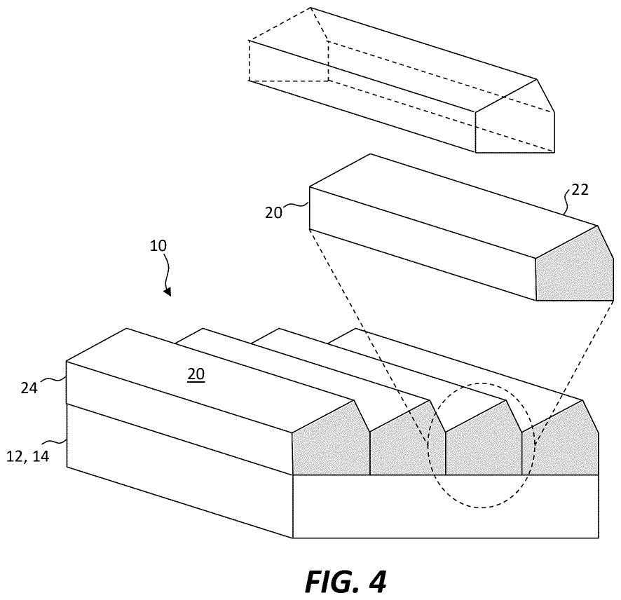

As shown in FIGS. 1 and 2, each stamp post 20 can be a separate stamp post 20 over rigid support 12 or mesa 14. For example, and as shown in FIGS. 1 and 2, sidewalls 24 or asymmetric distal surface 22 of each stamp post 20 is separated from and is not in contact with sidewalls 24 or asymmetric distal surface 22 of another different stamp post 20. In embodiments such as those illustrated in FIG. 3, each stamp post 20 is in contact with an adjacent or neighboring stamp post 20 so that a sidewall 24 or asymmetric distal surface 22 of a stamp post 20 is in contact with a sidewall 24 or asymmetric distal surface 22 of another different stamp post 20. Adjacent stamp posts 20 are stamp posts 20 between which there is no other stamp post 20 in a direction. In some embodiments, a sidewall 24 of adjacent stamp posts 20 are common. Each of stamp posts 20 in the array can be in contact with a neighboring stamp post 20 in one or two dimensions. FIG. 4 illustrates contact in one dimension; FIG. 3 illustrates contact in two dimensions over rigid support 12.

Stamp posts 20 that are in contact can be disposed directly on rigid support 12 or on mesa 14, as shown in FIG. 3, just as separated stamp posts 20 are as shown in FIGS. 1 and 2.

Each stamp post 20 can comprise an asymmetric distal surface 22 having a single asymmetric structure and intended or designed to contact a single component 30 for micro-transfer printing component 30, whether or not stamp posts 20 are in contact. In some embodiments, the multiple in-contact stamp posts 20 of FIG. 3 could be considered to form a single stamp post 20 with multiple asymmetric structures and the multiple asymmetric structures are intended or designed to contact a single component 30 for micro-transfer printing component 30. Generally, a stamp post 20 is intended to contact a single component 30 and asymmetric distal surface 22 of stamp post 20 can comprise a single asymmetric structure or multiple asymmetric structure. Multiple asymmetric structures can be substantially identical or can be different. As used herein, “substantially” means as intended or designed and are the same within manufacturing tolerances.

Asymmetric distal surface 22 can comprise multiple planar portions and can be asymmetric in two dimensions, for example as shown in FIGS. 1 to 3. In some embodiments, asymmetric distal surface 22 can comprise multiple planar portions and can be asymmetric in one dimension, for example as shown in FIG. 4. The planar portions of asymmetric distal surfaces 22 can be non-co-planar with a surface of rigid support 12 on or over which stamp posts 20 are disposed, again as shown in FIGS. 1 to 3. Thus, in embodiments, a micro-transfer-printing stamp 10 can comprise a one-dimensional or a two-dimensional array of stamp posts 20 disposed over rigid support 12. Each of stamp posts 20 can extend in a direction away from rigid support 12 to an asymmetric distal surface 22 of stamp post 20. Each stamp post 20 can comprise a one-dimensional or a two-dimensional array of asymmetric structures that can contact each other or that do not contact each other disposed over asymmetric distal surface 22 of stamp post 20. Each of stamp posts 20 can comprise a visco-elastic material such as PDMS.

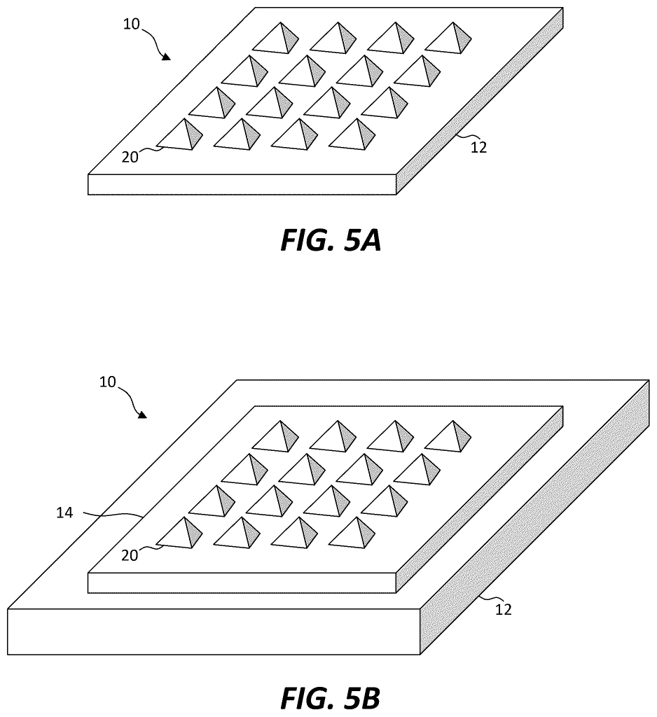

In some embodiments, planar portions of asymmetric distal surface 22 can be parallel to a surface of rigid support 12 on or over which stamp posts 20 are disposed. For example, if the multiple separated asymmetric structures of FIG. 2 are considered to comprise a single stamp post 20 on mesa 14, those portions of mesa 14 between the multiple separated asymmetric structures can be planar and parallel to the surface. In such embodiments, the asymmetric structures can be considered asymmetric micro-tips of a common stamp post 20 extending away from rigid support 12 and the planar portions. Such an asymmetric distal surface 22 with spatially separated asymmetric structures without sidewalls 24 are disposed on rigid support 12 is shown in FIG. 5A. FIG. 5B illustrates embodiments in which the spatially separated asymmetric structures without a sidewall 24 are disposed on mesa 14 (and mesa 14 is disposed on rigid support 12). As noted, each of the asymmetric structures can be a separate asymmetric distal surface 22 of a separate stamp post 20 (as indicated) or can form a single stamp post 20 with multiple separated asymmetric structures (not indicated in FIGS. 5A and 5B).

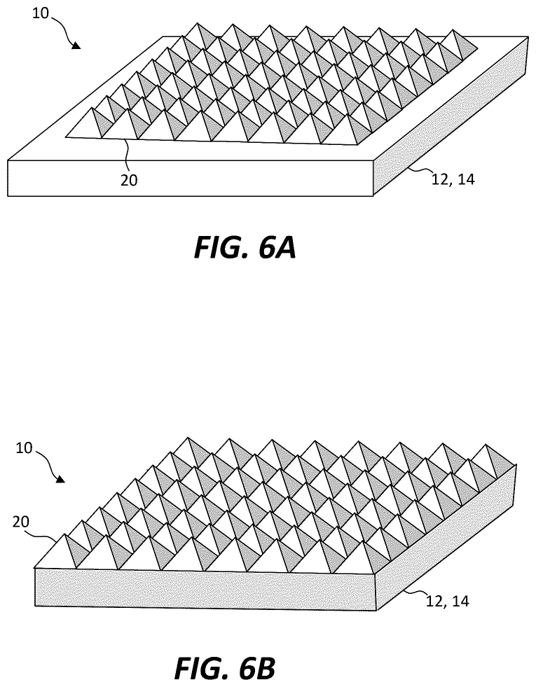

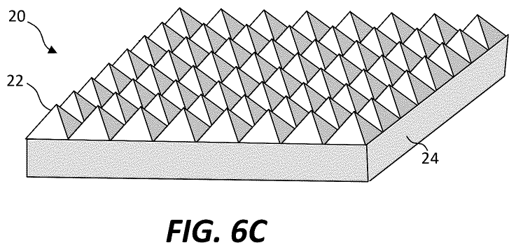

FIG. 6A shows a structure similar to that of FIG. 5A except that the asymmetric structures without any sidewall 24 are in contact with each other and disposed on rigid support 12 (or mesa 14) but do not extend to an edge of rigid support 12 or mesa 14. FIG. 6B shows the asymmetric structures without any sidewall 24 in contact with each other and disposed on mesa 14 or rigid support 12 that do extend to an edge of rigid support 12 or mesa 14. FIG. 3 illustrates the equivalent asymmetric structures with sidewalls 24 as FIG. 6A without sidewalls 24. FIG. 6C illustrates embodiments in which multiple asymmetric structures are disposed over an entire asymmetric distal surface 22 of stamp post 20 (or of each of multiple stamp posts 20), as opposed to a mesa 14 or rigid support 12, as in FIG. 6B.

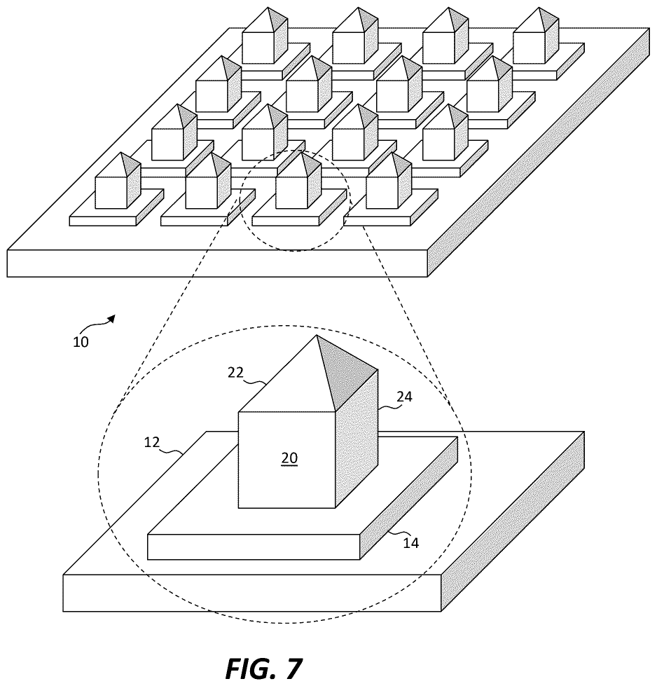

In embodiments and as shown in FIGS. 1-4, some embodiments comprise a single mesa 14 disposed on and in direct contact with rigid support 12 and a proximal end of each of multiple stamp posts 20 is on and in direct contact with the single mesa 14. In some embodiments multiple mesas 14 can be disposed on rigid support 12 and multiple stamp posts 20 can extend from each of the multiple mesas 14. In some embodiments and as shown in FIG. 7, each stamp post 20 is disposed on a single mesa 14 and each mesa 14 has only a single stamp post 20 extending from mesa 14. Thus, some embodiments comprise a separate mesa 14 for each of stamp posts 20 and each stamp post 20 extends from a different, separate mesa 14. Each mesa 14 can be on and in direct contact with rigid support 12 and a proximal end of each of stamp posts 20 can be on and in direct contact with a mesa 14.

In some embodiments (as discussed below), a proximal end of each of stamp posts 20 is in direct contact with rigid support 12.

In embodiments of the present disclosure, micro-transfer-printing stamps 10 are used for micro-transfer printing components 30 from a component source wafer 40 to a target substrate 50. A component 30 is picked up from component source wafer 40 by contacting distal surface 22 of stamp post 20 and adhering component 30 to distal surface 22. Stamp 10 is then removed from component source wafer 40 with component 30. The adhesion between component 30 and distal surface 22 is typically by vander Waals forces and must be less than the adhesion between stamp post 20 and rigid support 12. Rigid support 12 must be rigid to enable alignment of multiple stamp posts 20 to multiple components 30 across component source wafer 40. However, some materials, such as PDMS useful for providing visco-elastic, rate-dependent adhesion between a component 30 and distal surface 22 of stamp post 20, do not adhere sufficiently well to a useful transparent rigid support 12. If the adhesion between stamp post 20 and rigid support 12 is less than the adhesion between component 30 and stamp post 20, stamp post 20 will be ripped off rigid support 12 leaving component 30 and adhered stamp post 20 on component source wafer 40 so that component 30 is not removed. To prevent this undesirable outcome, an adhesion promoter can be provided between stamp post 20 and rigid support 12. In some embodiments, mesa 14 is provided between stamp post 20 and rigid support 12 to increase the area of PDMS provided in contact with rigid support 12 and thereby increasing the adhesion between stamp post 20 and rigid support 12.

Micro-transfer-printing stamps 10 can be constructed by coating a master stamp mold having a reverse shape of desired stamp 10 with a liquid material, such as PDMS, curing the PDMS, and then removing micro-transfer-printing stamp 10 from the mold. However, PDMS has a coefficient of expansion much larger than that of rigid support 12 and is therefore subject to shrinking during the cure process. This shrinking can misalign stamp posts 20, rendering stamp 10 difficult to use or with limited precision when printing. The stamp mold can be designed to accommodate the shrinkage, but issues with stamp post 20 position in the micro-transfer-printing stamp 10 can persist, causing alignment or picking problems for micro-assembled components 30 in micro-transfer-printed systems. For example, a micro-transfer-printing stamp 10 can comprise many thousands of micro-stamp posts 20 having lengths or widths of no more than one hundred, fifty, twenty, ten, five, two, or one micron over square millimeters of area. Even a minor difference between anticipated PDMS shrinking and actual shrinking can misalign posts spatially distant from each other across stamp 10. In some technology areas related to printing, this problem can be known as runout or run-out.

Runout can be mitigated by providing each stamp post 20 on an individual and separate mesa 14 disposed on rigid support 12. Because mesas 14 and stamp posts 20 are separated, individual, and physically disconnected, they will each shrink separately and no cumulative shrinkage (runout) across entire stamp 10 is present. Moreover, the relative area of each mesa 14 and stamp post 20 over rigid support 12 is small, so the actual shrinkage of each mesa 14 and stamp post 20 is correspondingly small. And, because stamp post 20 can be disposed at a center of mesa 14, shrinkage can be symmetric from the edges of mesa 14 to the center of mesa 14 so that the location of stamp post 20 over rigid support 12 can remain the same during the curing process, greatly improving precision in location and micro-transfer printing.

A method of constructing a stamp 10 in a mold is to fill the mold with liquid material (such as PDMS) and therefore all of mesas 14 or stamp posts 20 are physically connected, for example as shown in FIG. 2. To construct a micro-transfer-printing stamp 10 as shown in FIGS. 1 and 5 would require separately and individually filling each mesa 14 and stamp post 20 in a stamp mold (effectively requiring a separate mold for each mesa 14 and stamp post 20. Because the size of mesas 14 and stamp posts 20 are so small and, in commercial operation, there are so many stamp posts 20, this process is impractical.

Therefore, and according to some embodiments of the present disclosure, a micro-transfer-printing stamp 10, for example with separate stamp posts 20 or mesas 14, can be constructed using two-photon polymerization to provide individual and separate stamp posts 20 disposed directly on rigid support 12 (for example a glass substrate) as shown in FIG. 1 or to provide individual and separate mesas 14 disposed directly on rigid support 12. In some embodiments, only a single stamp post 20 extends from each mesa 14, as shown in FIG. 7. Thus, embodiments of the present disclosure comprise individual and spatially separated stamp posts 20 or mesas 14 each with an individual stamp post 20 disposed on rigid support 12. Such embodiments can provide more precise stamp post 20 alignment with components 30 on a component source wafer 40 during a micro-transfer printing pick (or pick up) operation.

Visco-elastic stamps 10 provide rate-dependent adhesion between a distal surface 22 of a stamp post 20 of a stamp 10 and an adhered component 30, as illustrated in FIGS. 8A-8F. The faster stamp 10 is pulled away from component 30, the stronger the adhesion between component 30 and stamp post 20 distal surface 22, and the slower stamp 10 is pulled away from component 30, the weaker the adhesion between component 30 and stamp post 20 distal surface 22. Thus, a component 30 can be picked from a component source wafer 40 with a stamp 10 by contacting component 30 to distal surface 22 of stamp post 20 and moving stamp 10 and adhered component 30 relatively quickly away from component source wafer 40. Component 30 can be printed onto a target substrate 50 by pressing component 30 to target substrate 50 and moving stamp 10 relatively slowly away from target substrate 50, leaving component 30 adhered to target substrate 50. The adhesion between component 30 and distal surface 22 of stamp post 20 also depends directly on an area of distal surface 22 in contact with component 30. The larger the distal surface 22 area of stamp post 20 in contact with component 30, the greater the adhesion between stamp post 20 and component 30. If distal surface 22 is planar and extends parallel to component 30 when not in contact with component 30 (e.g., in a relaxed state), the contact area can stay the same (e.g., is constant or static) when picking and printing.

According to embodiments of the present disclosure, the contact area between stamp post 20 distal surface 22 and component 30 is larger when picking than when printing. Thus, the contact area is dynamic (e.g., changes during the micro-transfer-printing process) and is not static. The change in contact area can be accomplished by providing a stamp post 20 distal surface 22 that is not planar or not parallel to component 30 (or rigid support 12), or both. In some embodiments, stamp post 20 distal surface 22 is an asymmetric distal surface 22. As shown in FIG. 8A, component 30 of component source wafer 40 is in contact with stamp post 20 asymmetric distal surface 22 in a relaxed state with no compression (or very little compression). In operation and as shown in FIG. 8B, flexible and elastic stamp post 20 (compressed stamp post 20C) distal surface 22 is compressed against component 30 to increase first contact area 74 between component 30 and stamp post 20 distal surface 22, for example at a first pressure. First contact area 74 can have a perimeter 75 surrounding first contact area 74. After relatively quickly removing component 30 from component source wafer 40 (shown in FIG. 8C), stamp 10 is no longer accelerated so that adhesion between stamp post 20 and component 30 reduces, and the elastic stamp post 20 material (e.g., PDMS) relaxes so that a second contact area 76 between stamp post 20 distal surface 22 and component 30 is reduced, as shown in FIG. 8D, and therefore the adhesion between stamp post 20 distal surface 22 and component 30 is likewise reduced. When printing as shown in FIG. 8E, component 30 is pressed against target substrate 50 with a second compression less than the first compression during picking and optionally close to zero, so that third contact area 78 is smaller than first contact area 74 during picking and the adhesion between component 30 and target substrate 50 is likewise smaller, improving the likelihood that component 30 will adhere to target substrate 50 rather than to stamp post 20 when slowly removing stamp 10 from target substrate 50 as shown in FIG. 8F, thereby improving print yields.

Third contact area 78 can be equal to or only slightly greater than second contact area 76 and less than first contact area 74. This technique can be especially useful when transfer printing to a target substrate 50 without an adhesive layer or to a target substrate 50 surface material that is less adhesive or more difficult to print. (Each of first, second and third contact areas 74, 76, 78 can have a perimeter 75 enclosing different areas that can be in continuous contact with component 30.)

According to embodiments of the present disclosure, a stamp post 20 with an asymmetric distal surface 22 can provide a greater difference in contact area between distal surface 22 and a component 30 adhered to distal surface 22 when compressed than when relaxed than a symmetric distal surface, for example a greater difference in first and second contact areas 74, 76 when stamp post 20 is compressed against component 30 than when stamp post 20 is not compressed against component 30 (e.g., stamp post 20 is relaxed), for example because a portion of asymmetric distal surface 22 can fold or bend over to expose a greater area of asymmetric distal surface 22 to component 30 with less pressure from stamp 10 against component 30.

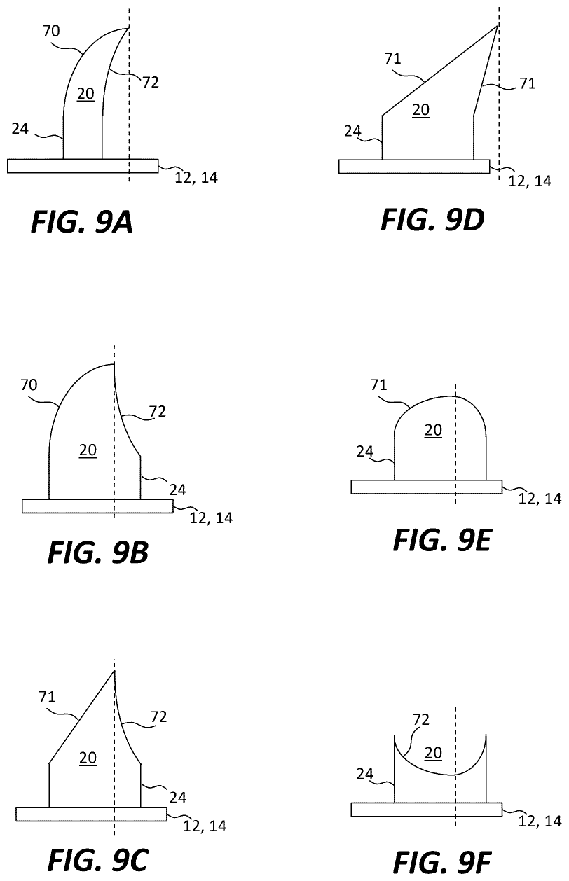

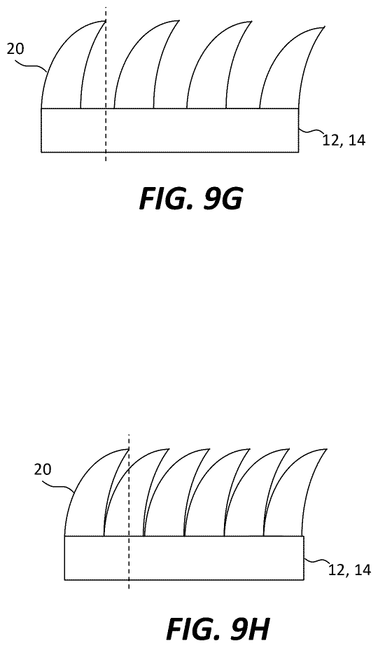

In some embodiments and as shown in FIGS. 1-8F, stamp posts 20 can be a polyhedron with polygonal, planar surfaces and distal surface 22 can comprise multiple polygons that meet at sharp corners (vertices) or lines (line segments where two polygons or faces of stamp post 20 or distal surface 22 meet). In some embodiments, distal surface 22 can comprise curved surfaces, or a combination of curved surfaces and polygons. FIG. 9A shows a stamp post 20 having sidewalls 24 orthogonal to a surface of rigid substrate 12 or mesa 14 that extend into a convex surface 70 (e.g., on the left side) and a concave surface 72 (e.g., on the right side) that meet at a point (the vertex) or a meeting line (if the convex curve and the concave curve continue parallel to a stamp sidewall 24). FIG. 9A illustrates embodiments in which the vertex or line is disposed beyond (e.g., not directly above or directly over) concave surface 72 so that a line or plane parallel to a sidewall 24 of stamp post 20 from the vertex or meeting line does not intersect stamp post 20 (except at the vertex or meeting line). Thus, in embodiments and as shown in FIG. 9A, a line projected through a point or surface of distal end 22 of asymmetric distal surface 22 farthest from rigid support 12 orthogonal to a surface of rigid support 12 does not intersect any other portion of asymmetric distal surface 22. Thus, a convex surface 70 and a concave surface 72 can meet at a point or meeting line farthest from rigid support 12 or mesa 14. In embodiments, a shortest line segment extending from a point on asymmetric distal surface 22 of stamp post 20 farthest from rigid support 12 orthogonally to rigid support 12 extends at least partially (or completely) exterior to stamp post 20.

FIG. 9B illustrates embodiments in which the line or plane parallel to a sidewall 24 of stamp post 20 does intersect stamp post 20, e.g., is directly above or directly over stamp post 20 and extends through a body of stamp post 20. Thus, in embodiments and as shown in FIG. 9B, a line or plane projected through a point, meeting line, or surface of distal end 22 of asymmetric distal surface 22 farthest from rigid support 12 orthogonal to a surface of rigid support 12 does intersect another portion of asymmetric distal surface 22, e.g., is directly over or directly above another portion of asymmetric distal surface 22.

FIG. 9C illustrates embodiments in which asymmetric distal surface 22 comprises both planar (polygonal) surfaces 71 and curved surfaces (e.g., convex surfaces 70 or concave surfaces 72, or a combination of these). In FIG. 9C, the vertex or meeting line at which the different surfaces of asymmetric distal surface 22 meet farthest from sidewalls 24 or rigid support 12 is directly above stamp post 20 (as in FIG. 9B) but could also be beyond (not be above) stamp post 20 or portions of stamp post 20 enclosed by sidewalls 24, as shown in FIG. 9A. Similarly, adjacent polyhedral surfaces of stamp post 20 can meet at a vertex or meeting line farthest from rigid support 12 above stamp post 20, as shown in FIGS. 1-8F, but could also extend beyond (not be directly above or directly over) stamp post 20 or portions of stamp post 20 enclosed by sidewalls 24 of stamp post 20.

FIG. 9D illustrates embodiments in which asymmetric distal surface 22 comprises planar (polygonal) surfaces 71. In FIG. 9D, the vertex or meeting line at which the different surfaces of asymmetric distal surface 22 meet farthest from sidewalls 24 or rigid support 12 could be directly above stamp post 20 (as in FIG. 9B) but is shown beyond (not above) stamp post 20 or portions of stamp post 20 enclosed by sidewalls 24, as shown in FIG. 9A. Thus, adjacent surfaces (e.g., adjacent polyhedral or curved surfaces) of distal end 22 of stamp post 20 can meet at a vertex or meting line farthest from rigid support 12 above stamp post 20 (as shown in FIGS. 1-8F, 9B, and 9C), but could also extend beyond (not be directly above or directly over) stamp post 20 or portions of stamp post 20 enclosed by sidewalls 24 of stamp post 20 (as shown in FIGS. 9A and 9D).

FIG. 9E illustrates embodiments in which asymmetric distal surface 22 comprises a continuous convex surface 70 and FIG. 9F illustrates embodiments in which asymmetric distal surface 22 comprises a continuous concave surface 72. The point or line farthest of asymmetric distal surface 22 farthest from rigid support 12 (FIG. 9E) or closest to rigid support 12 (FIG. 9F) is indicated with the orthogonal dashed line.

FIG. 9G illustrates a rigid support 12 or mesa 14 (or a proximal portion of a stamp post 20 comprising sidewalls 24) having multiple convex and concave structures that each comprise a stamp post 20 (disposed on rigid support 12 or mesa 14) or comprise multiple asymmetric distal structures in an asymmetric distal surface 22 of a single stamp post 20 that are spatially separated over rigid support 12, mesa 14, or portions of stamp post 20 enclosed by sidewalls 24 of stamp post 20. FIG. 9H illustrates embodiments in which stamp posts 20 or asymmetric distal structures on an asymmetric distal surface 22 of a stamp post 20 are in contact (e.g., sidewalls 24 are in contact), increasing the density of the asymmetric distal structures in asymmetric distal surface 22.

Asymmetric distal surfaces 22 or asymmetric distal structures of stamp posts 20 can provide a dynamic contact surface area in contact with a component 30 during micro-transfer printing that is larger when picking up a component 30 from a component source wafer 40 and smaller when printing component 30 to a target substrate 50, thereby providing greater adhesion between stamp post 20 and component 30 during the pick process and lesser adhesion between stamp post 20 and component 30 during the print process, thereby improving print yields.

The asymmetric distal structures can provide this change in contact area by bending or folding over or by preferentially exposing surface of faces of the asymmetric surface structure that are more horizontal than vertical, compressing greater the more vertical faces (where horizontal is parallel and vertical is orthogonal to a surface of rigid support 12 on which stamp posts 20 are disposed) of the asymmetric distal structures when the asymmetric distal structures are compressed against component 30. The folding or compressing can increase the area of asymmetric distal surface 22 that is in contact with component 30. When component 30 is removed from component source wafer 40, the compressed asymmetric distal structure(s) can relax, leaving component 30 adhered mostly (only, in the limit) to the vertices or meeting lines connecting faces of asymmetric distal surface 22, an area much smaller than the contact area of asymmetric distal surface 22 when stamp post 20 is compressed, and therefore providing less adhesion.

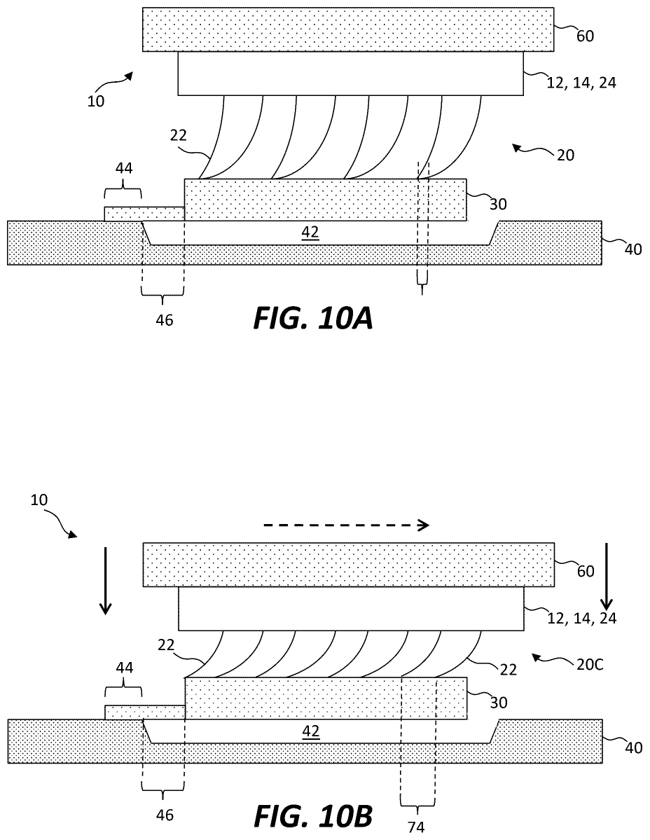

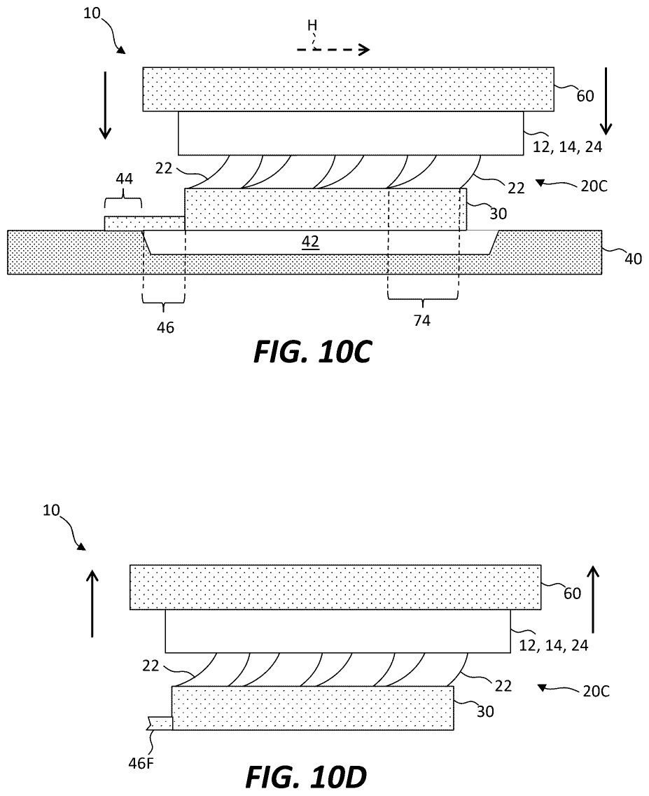

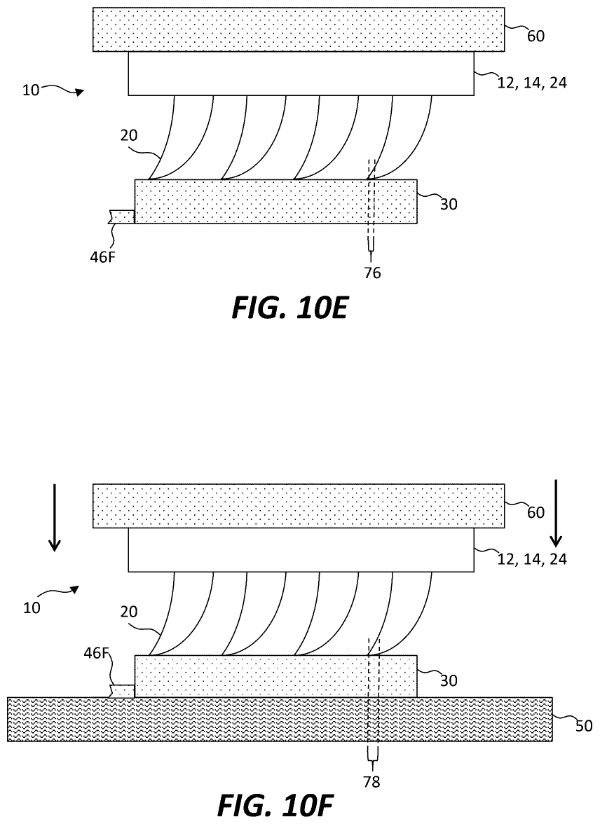

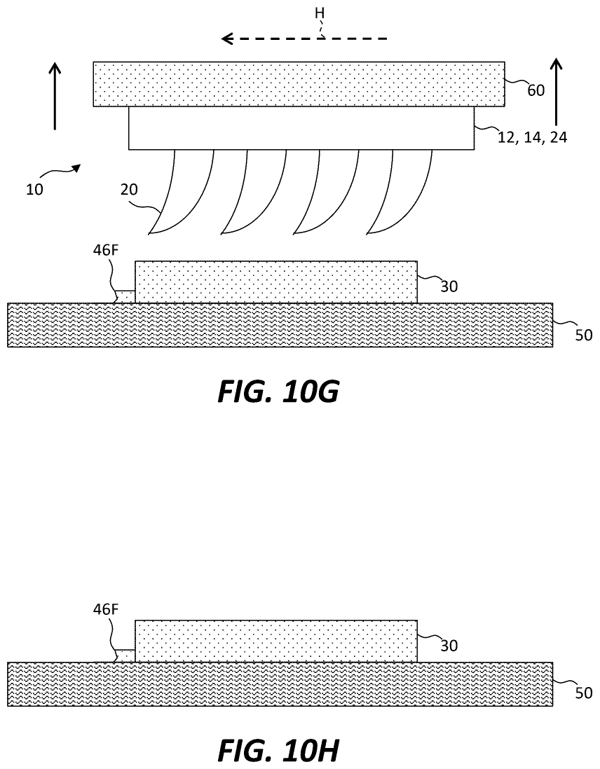

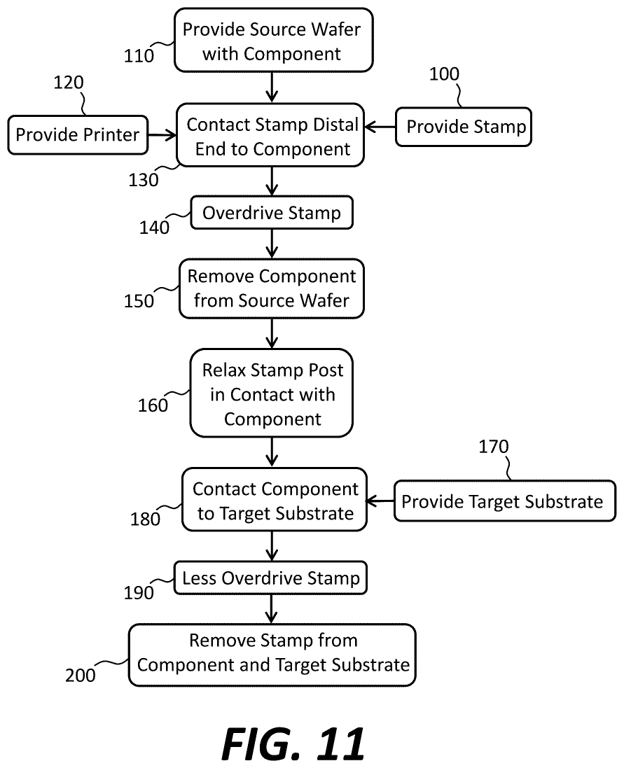

The successive cross sections of FIGS. 10A-10H and flow diagram of FIG. 11 illustrate a micro-transfer-printing process using a stamp post 20 with an asymmetric distal surface 22 according to embodiments of the present disclosure. As shown in FIG. 10A, a micro-transfer-printing stamp 10 is provided in step 100 that comprises a rigid support 12 with one or more stamp posts 20 disposed over rigid support 12 (e.g., either in direct contact with rigid support 12 or disposed on a mesa 14 disposed on rigid support 12). Stamp post(s) 20 each extend in a direction away from rigid support 12 to an asymmetric distal surface 22 of stamp post 20, for example extending orthogonally away from a surface of rigid support 12 on or over which stamp post(s) 20 are disposed. Stamp post 20 can comprise a visco-elastic material, for example PDMS. Asymmetric distal surface 22 can comprise one or more asymmetric distal structures. A component 30 provided in step 110 can be disposed on or over a component source wafer 40, separated from component source wafer 40 by a sacrificial portion 42, and connected to an anchor 44 portion of component source wafer 40 by one or more tethers 46 to suspend component 30 over component source wafer 40 with tether 46. A micro-transfer printer 60 comprising an optomechatronic control system for moving and aligning stamp 10, can be provided in step 120. In step 130, the asymmetric distal structure(s) of asymmetric distal surface 22 are brought into contact with a component 30, for example using micro-transfer printer 60.

As shown in FIG. 10A, only a relatively small contact area (shown with dashed lines) of asymmetric distal surface 22 is in contact with component 30 and stamp post 20. Each asymmetric distal structures on rigid support 12 or mesa 14 can be a separate asymmetric distal surface 22 of a separate stamp post 20 in contact with a common component 30 or the asymmetric distal structures can together comprise at least a portion of asymmetric distal surface 22 of stamp post 20. In typical use, each stamp post 20 contacts a single component 30 so, in FIGS. 10A-10G, asymmetric distal surface 22 comprises multiple curved and spatially separated asymmetric distal structures (but could comprise any one or combination of one or more spatially separated polyhedral asymmetric distal structures as shown in FIG. 1, polygonal and curved asymmetric distal structures as shown in FIG. 9A-9H, asymmetric distal structures that are spatially in contact as shown in FIGS. 6A-6B and 9E, a separate asymmetric distal surface 22 disposed directly on rigid support 12, or a separate asymmetric distal surface 22 disposed on mesa 14 on rigid support 12).

As shown in FIG. 10B and according to embodiments of the present disclosure, stamp post 20 is pressed against component 30 with micro-transfer printer 60 in step 140 (e.g., to overdrive stamp 10 vertically toward and past a point of contact between asymmetric distal surface 22 and a surface of component 30), as shown with the solid arrows, making stamp post 20 a compressed stamp post 20C, thereby compressing asymmetric distal surface 22 with a first pressure and providing a compressed first contact area 74 of asymmetric distal surface 22 in contact with component 30 and thereby increasing adhesion between asymmetric distal surface 22 and component 30. Asymmetric distal surface 22 can distort, fold over, or bend over to increase its adhered area. Micro-transfer printer 60 can also optionally move stamp 10 sideways (e.g., in a horizontal shear direction H parallel to the adhered surface of component 30 and a surface of component source wafer 40 on which component 30 is disposed shown by the dashed arrow, called pickup shear) to further distort and compress the asymmetric distal structure(s) (e.g., encouraging the asymmetric distal structures to fold or bend over and thereby increase first contact area 74 and consequent adhesion between asymmetric distal surface 22 and component 30). The horizontal pickup shear direction H can be in a direction (i) from a concave surface 72 to a convex surface 70, (ii) from a surface less parallel to a surface of rigid support 12 from which stamp post 20 extends to a surface more parallel to the surface, or (iii) from a center 26 of stamp post 20 to a point of stamp post 20 farthest from rigid support 12, or any one or combination of these, to enable folding or compressing the more vertical surface and thus increase the contact area. The movement in horizontal shear direction H can be less than an extent of component 30 in horizontal shear direction H. The compression and first contact area 74 can further increase as shown in FIG. 10C. As shown in FIG. 10C and in some embodiments, compressed asymmetric distal structure(s) can form a contiguous or nearly contiguous adhesion area over component 30 or can contact all of an exposed surface of component 30 with first contact area 74.

As shown in FIG. 10D, in step 150 stamp 10 can then be removed with component 30 from component source wafer 40 using micro-transfer printer 60 by moving stamp 10 and adhered component 30 vertically away from component source wafer 40, fracturing tether 46 to form fractured tether 46F. As stamp post 20 is no longer pressed against component 30 on component source wafer 40, compressed asymmetric distal structures of asymmetric distal surface 22 of compressed stamp post 20C can begin to relax in step 160, as shown in FIG. 10D until it is adhered to component 30 with a relatively smaller second contact area 76 as shown in FIG. 10E, reducing the adhesion between stamp post 20 asymmetric distal surface 22 and component 30. A target substrate 50 can be provided in step 170. Micro-transfer printer 60 can then relatively gently contact component 30 to a surface of a target substrate 50 in step 180 with a second pressure less than the first pressure to form third contact area 78 smaller than first contact area 74, for example without compressing (or only relatively slightly compressing) the asymmetric distal structures of stamp post 20 in step 190 (e.g., with less overdrive) to maintain the reduced adhesion between stamp post 20 asymmetric distal surface 22 and component 30 and enabling component 30 to relatively strongly adhere to target substrate 50, as shown in FIG. 10F.

This micro-transfer-printing process is especially useful when printing components 30 to a surface of target substrate 50 that is less adhesive, for example because of the material combinations or surface preparation of component 30 and a surface of target substrate 50. Micro-transfer printer 60 can then remove stamp 10 from target substrate 50 in step 200 as shown in FIG. 10G, leaving component 30 adhered to target substrate 50, as shown in FIG. 10H, completing the micro-transfer-printing process. During the printing process, stamp 10 can move in a horizontal shear direction H opposite that of horizontal shear direction H during the pickup process, shown by the dashed line in FIG. 10G, thus reducing third contact area 78.

According to embodiments of the present disclosure and as illustrated in FIG. 11, a method of transfer printing a component 30 from a component source wafer 40 to a target substrate 50 can comprise (i) providing a component source wafer 40 comprising component 30 suspended over a surface of component source wafer 40 with a tether 46 connecting component 30 to an anchor portion 44 of component source wafer 40 in step 110, (ii) providing target substrate 50 in step 170, and (iii) providing a micro-transfer-printer 60 and stamp 10 in step 120, for example having a stamp post 20 controlled by transfer printer 60. In step 130, stamp 10 is pressed against component 30 and optionally moved in a direction parallel to the surface when asymmetric distal surface (end) 22 of stamp post 20 is pressed against component 30, for example with transfer printer 60. By pressing stamp post 20 against component 30 (e.g., a top side of component 30 opposite component source wafer 40), distal surface 22 of stamp post 20 is adhered to component 30. By moving stamp 10 in a direction parallel to the surface, a first contact area 74 of distal surface 22 of stamp post 20 in contact with component 30 is increased by changing the shape of, e.g., bending or compressing, portions of stamp post 20 distal surface 22. In step 140, stamp post 20 is optionally overdriven by pushing stamp post 20 against component 30 to compress stamp post 20 (providing compressed stamp post 20C). Step 130 and step 140 can be a common movement in multiple directions at a same time. In step 150, component 30 can be removed from component source wafer 40 with micro-transfer-printing stamp 10 using transfer printer 60.

Stamp 10 with adhered component 30 is then transported, for example by transfer printer 60, to target substrate 50, provided in step 170. During the transportation, compressed portions of stamp post 20 can decompress or relax in step 160, as stamp post 20 can be an elastic material and can at least partly resume its shape prior to pressing stamp post 20 against component 30. The decompression or relaxation of stamp post 20 can reduce second contact area 76 of distal surface 22 of stamp post 20 in contact with component 30, thereby reducing the adhesion between distal surface 22 of stamp post 20 and component 30. Component 30 is then pressed against target substrate 50 with transfer printer 60 in step 180. In embodiments, the second pressure (and overdrive) contacting component 30 to transfer printer 60 is minimal, for example close to zero, zero, or less than, e.g., substantially less than, the first pressure (and overdrive) during the picking step 150 with which component 30 was removed from component source wafer 40 in step 190. By using less pressure (and overdrive) for printing than picking third contact area 78 between distal surface 22 of stamp post 20 in contact with component 30 is not increased or at least not increased to the same extent so that a third contact area 78 of distal surface 22 in contact with component 30 is not increased to the same extent as first contact area 74, thus ensuring that the adhesion between component 30 and distal surface 22 is less for printing (step 180) than for picking (step 150). This reduced adhesion between component 30 and distal surface 22 enables component 30 transfer to target substrate 50 easier and with higher yields, since the relative adhesion between distal surface 22 and component 30 is reduced compared to the adhesion between component 30 and target substrate 50. Stamp 10 can then be removed from component 30 and target substrate 50 in step 200.

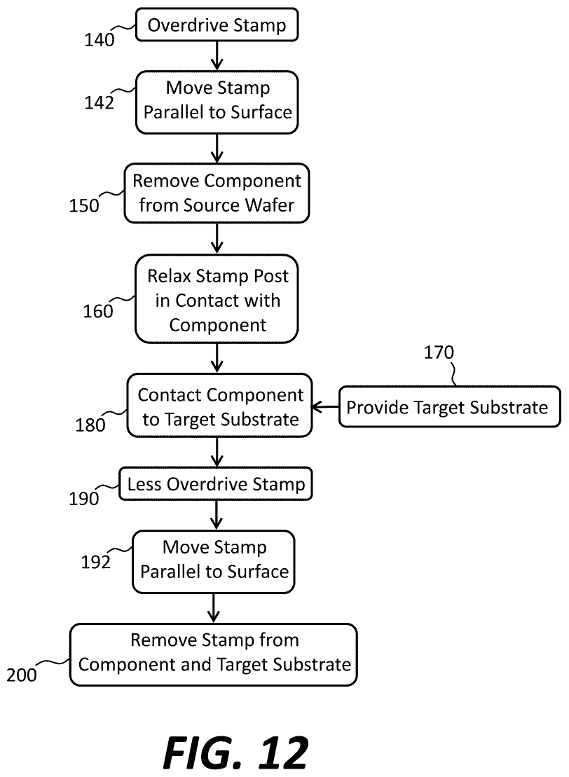

According to embodiments of the present disclosure and as illustrated in FIG. 12, a method of transfer printing a component 30 from a component source wafer 40 to a target substrate 50 can comprise (i) providing a component source wafer 40 comprising component 30 suspended over a surface of component source wafer 40 with a tether 46 connecting component 30 to an anchor portion 44 of component source wafer 40 in step 110, (ii) providing target substrate 50 in step 170, and (iii) providing a micro-transfer-printing stamp 10 in step 120, for example having a stamp post 20 and controlled by a transfer printer 60. Using a transfer printer 60, stamp post 20 of stamp 10 can be pressed against component 30 in step 140 and moved in a direction parallel to the surface in step 142. Steps 140 and 142 can be at a same time and can be a same movement, e.g., vertically and horizontally. The horizontal movement can be in a direction that most increases an area of distal surface 22 in contact with component 30, e.g., depending on the structure of asymmetric distal surface 22. By pressing asymmetric distal surface 22 of stamp post 20 against component 30, component 30 is adhered to distal surface 22 of stamp post 20, for example using vander Waals forces. Component 30 can be removed from component source wafer 40 with micro-transfer-printing stamp 10 using transfer printer 60 in step 150 and pressed against target substrate 50 to adhere component 30 to target substrate 50 in step 180 with less overdrive (step 190), after stamp post 20 (or the material comprising stamp post 20) relaxes or decompresses in step 160. Steps 180 and 190 can be a same step performed at a same time in a common movement of stamp 10. Micro-transfer-printing stamp 10 can be removed from target substrate 50 with transfer printer 60 in step 200.

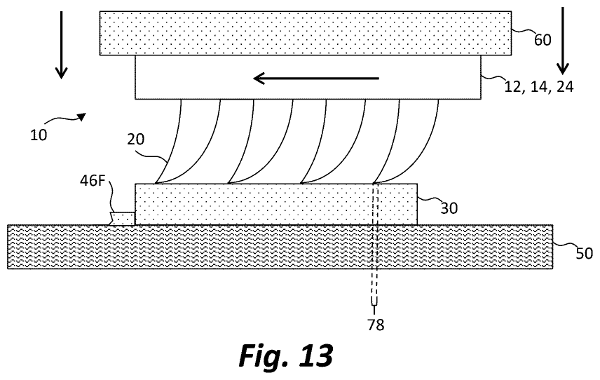

In embodiments, the motion of stamp post 20 in steps 180 and 190 are completely vertical, e.g., do not have a substantial horizontal direction, within the capabilities of transfer printer 60. Some other embodiments comprise moving stamp 10 in a direction parallel to the surface using transfer printer 60 during the printing step (e.g., steps 180 and 190). The direction parallel to the surface can be at least partially opposite to the direction parallel to the surface during the pick step (e.g., step 142 of FIG. 12, as shown in FIG. 13). By moving stamp post 20 horizontally in an opposite direction using transfer printer 60 during printing (steps 180, 190), a third contact area 78 (e.g., less than first contact area 74 and no or only slightly greater than second contact area 76) between component 30 and distal surface 22 can be further reduced, thus further reducing the adhesion between component 30 and distal surface 22, thereby enabling printing with greater yields, as shown in FIG. 13 with adhered third contact area 78 reduced in consequence of the horizontal movement of stamp 10 and distal surface 22 of stamp post 20. Moving stamp post 20 horizontally in an opposite direction using transfer printer 60 during printing can be performed while transfer printer 60 is moving toward target substrate 50, while transfer printer 60 is moving away from target substrate 50, or both.

Asymmetric distal surface 22 can have a variety of shapes. In some embodiments, and as shown in FIGS. 1-10H, stamp post 20 has stamp post sides 24 and a center 26 equidistant from stamp post sides 24. As shown in FIG. 1, a line projected through a point or surface of distal end 22 of asymmetric distal surface 22 farthest from rigid support 12 orthogonal to a surface of rigid support 12 does not intersect center 26 in at least one dimension. The point or surface of distal end 22 of asymmetric distal surface 22 farthest from rigid support 12 can be called the farthest point (even if it is an area of distal end 22). The surface of rigid support 12 can be a surface on which stamp 10 or stamp post 20 is disposed and from which stamp post 20 extends. In some embodiments, the direction parallel to the surface is at least partially a direction from the farthest point to center 26 or generally toward center 26 or away from the farthest point. In some embodiments, the direction parallel to the surface is at least partially a direction away from the center 26 toward the farthest point or generally away from center 26 or toward the farthest point. Because stamp post 20 can be an elastic material, a movement of stamp post 20 parallel to a surface of component 30 when in contact with component 30 can deform stamp post 20 and increase or decrease the contact area of distal end 22 in contact with component 30 and thereby increase or decrease the adhesion between distal surface 22 and component 30, enabling an easier component 30 pick up from component source wafer 40 or component 30 print to target substrate 50, respectively. Generally, moving stamp post 20 horizontally away from the farthest point can increase the adhesion area of distal surface 22 in contact with component 30 and moving stamp post 20 horizontally toward the farthest point can decrease the adhesion area of distal surface 22 in contact with component 30.

In some embodiments and as shown in FIGS. 9A-9B, asymmetric distal surface 22 can have different surface portions, one surface portion of which can be a concave continuous surface and another surface portion that is a convex continuous surface and the direction parallel to the surface in step can be at least partially a direction from the convex surface 70 to the concave surface 72 or can be at least partially a direction from the concave surface 72 to convex surface 70. In some embodiments, asymmetric distal surface 22 can comprise multiple different continuous surface portions. A larger (e.g., largest) continuous surface portion can have a larger area larger than an area of any or some of the other continuous surface portions over target substrate 50 (e.g., projected orthogonally onto target substrate 50). Similarly, a smaller continuous surface portion of the continuous surface portions can have a smaller area over target substrate 50 smaller than a larger or largest area (e.g., projected orthogonally onto target substrate 50). Some embodiments can comprise moving stamp post 20 from an edge of stamp post 20 toward the largest continuous surface portion, thereby changing the contact area of distal surface 22 in contact with component 30 and the adhesion between distal surface 22 and component 30.

According to embodiments of the present disclosure, a method of picking a component 30 from a component source wafer 40 with a stamp 10 using a transfer printer 60 can comprise providing component source wafer 40, stamp 10, and transfer printer 60. Pressing a distal surface 22 of a stamp post 20 of stamp 10 against component 30 with transfer printer 60 so that at least some portion of stamp post 20 folds over and adhere component 30 to distal surface 22. Transfer printer 60 can remove stamp 10 and component 30 adhered to stamp 10 from component source wafer 40. To fold a portion of stamp post 20 over can be to position a portion of distal surface 22 back over itself, e.g., in a direction orthogonal to rigid support 12. Folding a portion of distal surface 22 of stamp post 20 back over itself can increase the area (and adhesion) between stamp post 20 and component 30 when stamp post 20 is pressed against component 30.

According to some embodiments of the present disclosure and as shown in FIG. 1, a micro-transfer-printing stamp 10 can comprise a rigid support 12 and a visco-elastic stamp post 20 disposed directly on and extending away from rigid support 12. According to some embodiments of the present disclosure and as shown in FIG. 2, a micro-transfer-printing stamp 10 can comprise a rigid support 12, a visco-elastic mesa 14 disposed on rigid support 12, and a visco-elastic stamp post 20 disposed directly on and extending away from mesa 14 and extending away from rigid support 12. According to some embodiments of the present disclosure and as shown in FIG. 7, a micro-transfer-printing stamp 10 can comprise a rigid support 12, a plurality of visco-elastic mesas 14, each individually disposed on rigid support 12, and a single visco-elastic stamp post 20 disposed directly on each of mesas 14 and extending away from each mesa 14 and extending away from rigid support 12. Each of single visco-elastic stamp posts 20 can be disposed directly over a center of mesa 14 on which single visco-elastic stamp post 20 is directly disposed. In some embodiments, a center 26 of each of single visco-elastic stamp posts 20 is disposed directly over a center of mesa 14 on which single visco-elastic stamp post 20 is directly disposed.

In some embodiments, asymmetric distal surface 22 of stamp post 20 of stamp 10 can comprise curved surfaces, for example continuous curved surfaces or one or more portions of one or more continuous curved surface. (By continuous is meant that a mathematical expression of the curved surface is differentiable. Planar portions are also continuous. The point, as shown in FIGS. 1-3, or meeting line, as shown in FIG. 4, at which different surfaces of asymmetric distal surface 22 meet is discontinuous and non-differentiable, for example the point or line of asymmetric distal surface 22 farthest from rigid support 12. In some embodiments, a portion of asymmetric distal surface 22 farthest from rigid support 12 can be continuous, not shown in the Figures but could be realized with a continuous curved surface that comprises the portion of asymmetric distal surface 22 farthest from rigid support 12.

In some embodiments, distal surface 22 (i) has a convex surface 70 curved in two dimensions, e.g., as with a sphere, ellipsoid, or an oblate solid, (ii) is a hemisphere, a portion of a hemisphere, an ellipsoid, or a portion of an ellipsoid, (iii) has a convex surface 70 curved in one dimension, e.g., as with the surface of a cylinder, (iv) has a shape of at least a portion of a cylindrical surface, (v) has a concave surface 72 curved in two dimensions, e.g., as with a sphere, ellipsoid, or an oblate solid, (vi) is a hemisphere, a portion of a hemisphere, an ellipsoid, or a portion of an ellipsoid, (vii) has a concave surface 72 curved in one dimension, e.g., as with the surface of a cylinder, or (viii) distal surface 22 has a shape of at least a portion of a cylindrical surface.

In some embodiments of the present disclosure, distal surface 22 of each stamp post 20 is continuously curved or is discontinuous or has portions that are flat, for example a central flat portion 23 for concave or convex embodiments. In some embodiments a perimeter or edge portion of distal surface 22 is flat for concave or convex embodiments. A flat portion of distal surface 22 can be substantially parallel to a surface of rigid support 12 or mesa 14 on which stamp posts 20 are disposed and from which stamp posts 20 extend, e.g., orthogonally. Distal surface 22 can include a flat portion and can extend from a sidewall 24 to an opposing sidewall 24 of stamp post 20. In some embodiments, distal surface 22 of stamp post 20 is continuously and completely curved and has a variable radius of curvature, for example distal surface 22 can comprise or have a shape of a portion of an ellipse. The radius of curvature can be greatest at center 26 of distal surface 22 so that the central portion of distal surface 22 is flatter than an edge portion of distal surface 22 adjacent to or in contact with sidewall 24. In some other embodiments, portions of distal surface 22 can have a constant radius of curvature. In embodiments, those portions of distal surface 22 that are not flat can have a variable or constant radius of curvature.

Stamp posts 20 can have a curved, circular, or oval cross section in a direction parallel to a surface of rigid support 12 from which mesa 14 or stamp posts 20 extend. In some embodiments, portions of stamp posts 20 can have a rectangular cross section parallel to a surface of rigid support 12 from which mesa 14 or stamp posts 20 extend. Thus, in embodiments, flat portions can form at least a portion of a curved ring or rectangular perimeter surface and a center 26 of distal surface 22 can be surrounded by portions of distal surface 22 that have a different distance from rigid support 12 than a distance of center 26 to rigid support 12.

Embodiments of the present disclosure provide a method for enhancing the difference in adhesion between picking and printing a component 30 during micro-transfer printing by increasing a difference in adhered contact area of distal surface 22 and component 30 between picking and printing, thereby increasing micro-transfer printing yields. This difference can be in addition to differences in adhesion due to rate-dependent effects (e.g., picking at a faster separation rate and printing at a slower separation rate). Furthermore, embodiments of the present disclosure provide a method for micro-transfer printing that does not require shear when printing (e.g., does not require horizontal movement of component 30 while in contact with target substrate 50). This can improve printing precision (e.g., locating component 30 more precisely where desired on target substrate 50). Furthermore, embodiments of the present disclosure can support a wider range of pick and print parameters, circumstances, or conditions because a greater range of adhesion differences between distal surface 22 and component 30 is possible at different steps in the micro-transfer printing operation.

In some embodiments, an adhesive layer is provided on target substrate 50 to enhance adhesion between components 30 and target substrate 50. However, in some applications such an adhesive layer is undesirable or impractical so that printing to the target substrate 50 is more difficult. Using asymmetric stamp posts 20 in embodiments of the present disclosure can enable or facilitate printing to target substrate 50 without any adhesive layer since the adhesion between distal surface 22 and component 30 can be reduced using embodiments of the present disclosure.

Embodiments of the present disclosure can be made in a variety of ways, for example using photolithographic methods and materials (e.g., with a master mold constructed photolithographically or otherwise). For example, a master wafer (e.g., a mold substrate such as a silicon substrate) can be provided and coated with a patterned protection layer (e.g., a patterned photoresist) having a hole exposing a portion of the master wafer. The master wafer is then exposed to an etchant (e.g., XeF2) through the hole to etch a curved cavity or hole in master wafer. The patterned protection layer can then be stripped (e.g., with a chemical etch).

In some embodiments, 3D printing can be used make master molds from which stamps 10 can be produced. In some embodiments, a master mold (e.g., a stamp mold) can be made using 3D printing, for example using two-photon polymerization to cure a patterned structure (e.g., using a polymer such as an acrylic and light with two-photon polymerization) and cavity on a base (e.g., a rigid support 12 such as glass or a silicon master wafer), curing the patterned structure, and then forming stamp 10. The cured structure can then be then rinsed.

A master mold can be treated, for example fluorinated, or otherwise coated to enhance and enable the removal of stamp 10 from the master mold. Treatment or coating can be made, for example, using a liquid or a gas, by applying a solid (e.g., a solid-phase coating), or by processing one or more surfaces of a master mold (e.g., mechanically processing).

Stamps 10 having stamp posts 20 with asymmetric distal ends 22 can be constructed using the master mold. The patterned structure and master wafer are coated with an elastic stamp material (such as PDMS) against rigid support 12 and then cured, for example with heat or radiation, for example for some hours (e.g., 8 hours) at an elevated temperature, for example 60° C., and then removed from the mold, to provide stamp 10.

In some embodiments, stamps 10 can be made directly on a polymer-coated substrate using two-photon polymerization to cure a stamp structure on the substrate and then rinsing the structure.

Stamp 10 can then be used to print components 30 from a component source wafer 40 to a target substrate 50.

According to some embodiments of the present disclosure, a micro-transfer-printing stamp 10 comprises components 30 disposed on distal end 22 of stamp posts 20. According to some embodiments of the present disclosure, components 30 are physically attached to anchor 44 with tether 46 exclusively and directly over sacrificial portions 42, suspended over component source wafer 40, and adhered to stamp posts 20 of stamp 10. According to some embodiments of the present disclosure, components 30 with fractured tethers 46F are disposed on and adhered to target substrate 50 and adhered to stamp posts 20 of stamp 10.

The height of stamp posts 20 can be, for example, 10-50 microns and can be at least or no greater than two microns, at least or no greater than five microns, at least or no greater than ten microns, at least or no greater than fifteen microns, or at least or no greater than twenty microns. The desired height can depend on component 30 size, the Young's modulus of stamp post 20 and stamp material, and the rate at which stamp 10 is moved with respect to component source wafer 40 or target substrate 50. Stamp posts 20 can have a distal end 22 with an area similar to the area (length by width) of components 30, somewhat smaller, or somewhat larger. The area of distal end 22 (farthest from rigid support 12) can have an area no greater than the area of components 30, for example no greater than 80%, no greater than 50%, or no greater than 25% of distal end 22.

The positions and movements of stamps 10, component source wafer 40, and target substrate 50 can be controlled by a motion platform (e.g., a 2D or 3D motion platform controlling horizontal, vertical, and rotational movement and alignment), for example transfer printer 60. For example, stamp 10, component source wafer 40, and target substrate 50 can be in contact with, and their movements controlled by, the motion platform. A motion platform can be a mechatronic system that uses an optical camera to align stamp 10 to component source wafer 40, components 30, and target substrate 50. Components 30 can be integrated circuits or layers of material or other structures released (e.g., by etching) from component source wafer 40.

A transfer printer 60 may include motion-plus-optics machinery (e.g., an opto-mechatronic motion platform) for performing print operations. For example, transfer printer 60 may include stamp 10 mounted onto motion-plus-optics machinery (e.g., an opto-mechatronic motion platform) in order to precisely control alignment and kinetics of with respect to a source wafer of components 30 and stamp 10. In some embodiments, during micro-transfer printing a motion platform of a transfer printer 60 brings stamp 10 into contact with components 30 on component source wafer 40, with optical alignment performed before contact. In some embodiments, rapid upward movement of the print-head (or, in some embodiments, downward movement of component source wafer 40) breaks (e.g., fractures) or separates component tether(s) 46 forming broken (e.g., fractured) or separated component tethers 46, transferring component(s) 30 to distal surface(s) 22 of stamp post 20 ends of stamp 10. In some embodiments, the populated stamp 10 then travels to target substrate 50 (or vice versa) and one or more components 30 are then printed.

Mesa 14 can comprise a same stamp material as stamp posts 20 and can be equally flexible (e.g., have a common Young's modulus). In some embodiments, mesa 14 comprises the same stamp material(s) as stamp posts 20 but in different proportions, so that stamp posts 20 are more flexible than mesa 14. In some embodiments, mesa 14 comprises different stamp materials than stamp posts 20 and stamp posts 20 are more flexible than mesa 14 (e.g., have a lower Young's modulus). According to some embodiments, mesa 14 can comprise a common mesa 14 or comprise separate mesas 14 each supporting a subset of stamp posts 20. Rigid support 12 can be, for example, any suitable wafer or rigid structure with a substantially planar surface suitable for processing, for example glass, silicon, sapphire, or quartz. Rigid support 12 can be less flexible than mesa 14 and less flexible than stamp posts 20.

In certain embodiments, component source wafer 40 can be any structure with a surface suitable for forming patterned sacrificial layers having sacrificial portions 42 (or an etched gap), anchors 44, tethers 46, and disposing or forming patterned components 30. For example, component source wafers 40 can comprise a semiconductor or compound semiconductor and can comprise an etchable sacrificial layer comprising material different (e.g., an oxide) from material of component source wafer 40. Any one or more of component source wafer 40 and sacrificial portion 42 can comprise an anisotropically etchable material. Suitable semiconductor materials can be silicon or silicon with a (100) or (111) crystal structure (e.g., orientation). A surface of component source wafer 40 can be substantially planar and suitable for photolithographic processing, for example as found in the integrated circuit or MEMs art.

Components 30 according to embodiments of the present disclosure can be micro-components 30 and stamp posts 20 can be correspondingly small. For example, components 30 can have a length or width no greater than 200 microns, no greater than 100 microns, no greater than 50 microns, no greater than 20 microns, no greater than 10 microns, no greater than 5 microns, or no greater than 2 microns. The thickness of components 30 can be no greater than 50 microns, no greater than 20 microns, no greater than 10 microns, no greater than 5 microns, no greater than two microns, no greater than one micron, or no greater than 0.5 microns.

Components 30 can be native to component source wafer 40 and each component 30 can be disposed completely and entirely over sacrificial portion 42. Component source wafer 40 can comprise a sacrificial layer comprising sacrificial portions 42 laterally separated by anchors 44. Components 30 can be physically connected to anchors 44 by tethers 46. In embodiments, sacrificial portions 42 are sacrificed, for example by dry or wet etching, so that sacrificial material in sacrificial portions 42 is removed to form a gap between component 30 and component source wafer 40.

Component 30 can be encapsulated by an encapsulation layer to protect component 30 from environmental contaminants. The encapsulation layer can also coat portions of component source wafer 40 and anchors 44. In some embodiments, tether 46 comprises portions of an encapsulation layer or a portion of an encapsulation layer forms tether 46. Component 30 can comprise an encapsulation layer and tether 46 or a portion (e.g., fractured or separated portion) of tether 46F.

In some embodiments of the present disclosure, components 30 are small integrated circuits or micro-electro-mechanical (MEMS) devices, for example chiplets (e.g., micro-chiplets). Component 30 can have any suitable aspect ratio or size in any dimension and any useful shape, for example a rectangular cross section or rectangular top or rectangular bottom surface. Components 30 can be micro-components 30, for example having at least one dimension that is in the micron range, for example having a planar extent from 2 microns by 5 microns to 200 microns by 500 microns (e.g., an extent of 2 microns by 5 microns, 20 microns by 50 microns, or 200 microns by 500 microns) and, optionally, a thickness of from 200 nm to 200 microns (e.g., at least or no more than 2 microns, 20 microns, or 200 microns). Components 30 can have a thin substrate with at least one of (i) a thickness of only a few microns, for example less than or equal to 25 microns, less than or equal to 15 microns, or less than or equal to 10 microns, (ii) a width of 5-1000 microns (e.g., 5-10 microns, 10-50 microns, 50-100 microns, or 100-1000 microns) and (iii) a length of 5-1000 microns (e.g., 5-10 microns, 10-50 microns, 50-100 microns, or 100-1000 microns).

Such micro-components 30 can be made in a native source semiconductor wafer (e.g., a silicon wafer or compound semiconductor wafer such as component source wafer 40) having a process side and a back side used to handle and transport the wafer using lithographic processes. Components 30 can be formed using lithographic processes in an active layer on or in the process side of component source wafer 40. Methods of forming such structures are described, for example, in U.S. Pat. No. 8,889,485. According to some embodiments of the present disclosure, component source wafers 40 can be provided with components 30, a sacrificial layer (a release layer), sacrificial portions 42 anchors 44, and tethers 46 already formed, or they can be constructed as part of a process in accordance with certain embodiments of the present disclosure.

In certain embodiments, components 30 can be constructed using foundry fabrication processes used in the art. Layers of materials can be used, including materials such as metals, oxides, nitrides and other materials used in the integrated-circuit art. Components 30 can have different sizes, for example, less than 1000 square microns or less than 10,000 square microns, less than 100,000 square microns, or less than 1 square mm, or larger. Components 30 can have variable aspect ratios, for example at least 1:1, at least 2:1, at least 5:1, or at least 10:1. Components 30 can be rectangular or can have other shapes.

A component 30 can be an active circuit component 30, for example including one or more active electronic elements such as electronic transistors or diodes or light-emitting diodes or photodiodes that produce an electrical current in response to ambient light. A component 30 can be a passive component 30, for example including one or more passive elements such as resistors, capacitors, or conductors. In some embodiments, component 30 includes both active and passive elements. Component 30 can be a semiconductor device having one or more semiconductor layers, such as an integrated circuit. Component 30 can be an unpackaged die. In some embodiments, component 30 is a compound device having a plurality of active or passive elements, such as multiple semiconductor components 30 with separate substrates, each with one or more active elements or passive elements, or both. Components 30 can be or include, for example, electronic processors, controllers, drivers, light-emitting diodes, photodiodes, light-control devices, light-management devices, piezoelectric devices, acoustic wave devices (e.g., acoustic wave filters), optoelectronic devices, electromechanical devices (e.g., microelectromechanical devices), photovoltaic devices, sensor devices, photonic devices, magnetic devices (e.g., memory devices), or elements thereof. A device can be or include, for example, electronic processors, controllers, drivers, light-emitting diodes, photodiodes, light-control devices, light-management devices, piezoelectric devices, acoustic wave devices (e.g., acoustic wave filters), optoelectronic devices, electromechanical devices (e.g., microelectromechanical devices), photovoltaic devices, sensor devices, photonic devices, magnetic devices (e.g., memory devices).

As is understood by those skilled in the art, the terms “over” and “under” are relative terms and can be interchanged in reference to different orientations of the layers, elements, and substrates included in the present disclosure. For example, a first layer on a second layer, in some implementations means a first layer directly on and in contact with a second layer. In other implementations, a first layer on a second layer includes a first layer and a second layer with another layer therebetween.

Having described certain implementations of embodiments, it will now become apparent to one of skill in the art that other implementations incorporating the concepts of the disclosure may be used. Therefore, the disclosure should not be limited to certain implementations, but rather should be limited only by the spirit and scope of the following claims.

Throughout the description, where apparatus and systems are described as having, including, or comprising specific elements, or where processes and methods are described as having, including, or comprising specific steps, it is contemplated that, additionally, there are apparatus, and systems of the disclosed technology that consist essentially of, or consist of, the recited components, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously. The disclosure has been described in detail with particular reference to certain embodiments thereof, but it will be understood that variations and modifications can be effected within the spirit and scope of the claimed invention.

### PARTS LIST

A cross section
H horizontal shear direction
10 stamp/micro-transfer-printing stamp
12 rigid support
14 mesa/bulk
20 post/stamp post
20C compressed stamp post
22 distal end/distal surface/asymmetric distal surface
24 sidewall/stamp post side/stamp post edge
26 center
30 component
40 component source wafer/component source substrate
42 sacrificial portion
44 anchor/anchor portion
46 tether
46F fractured tether
50 target substrate
60 transfer printer/micro-transfer printer
70 convex surface
71 polygonal surface
72 concave surface
74 contact area/first contact area
75 perimeter
76 second contact area
78 third contact area
100 provide source wafer with component step
110 provide stamp step
120 provide printer step
130 contact stamp distal end to component step
140 overdrive stamp step
150 remove component from source wafer step
160 relax stamp post in contact with component step
170 provide target substrate step
180 contact component to target substrate step
190 less overdrive stamp step
200 remove stamp from component and target substrate step

1. A micro-transfer-printing stamp, comprising:
a rigid support;
a stamp post disposed over the rigid support, the stamp post extending in a direction away from the rigid support to a non-planar asymmetric distal surface of the stamp post and operable to contact a component surface when the stamp post is pressed against the component surface thereby defining a contact area having a perimeter within which the asymmetric distal surface continuously contacts the surface, wherein the stamp post comprises a visco-elastic material.

2. The micro-transfer-printing stamp of claim 1, wherein the asymmetric distal surface comprises multiple planar sidewalls that extend away from the rigid support and form a perimeter comprising line segments surrounding the asymmetric distal surface.

3. The micro-transfer-printing stamp of claim 1, wherein a perimeter of the asymmetric distal surface comprises a curve.

4-5. (canceled)

6. The micro-transfer-printing stamp of claim 1, wherein the asymmetric distal surface comprises a planar portion and one or more micro-tip portions and the one or more micro-tip portions each comprise an asymmetric micro-tip extending from the planar portion.

7. The micro-transfer-printing stamp of claim 1, (i) wherein a proximal end of the stamp post is in direct contact with the rigid support; or (ii) comprising a single mesa disposed on and in direct contact with the rigid support and a proximal end of the stamp post is on and in direct contact with the mesa.

8. (canceled)

9. The micro-transfer-printing stamp of claim 1, comprising a one-dimensional or a two-dimensional array of stamp posts disposed over the rigid support, each of the stamp posts extending in a direction away from the rigid support to an asymmetric distal surface of the stamp post, and wherein each of the stamp posts comprises a visco-elastic material.

10. The micro-transfer-printing stamp of claim 9, wherein a proximal end of each of the stamp posts is in direct contact with the rigid support.

11. The micro-transfer-printing stamp of claim 9, comprising a single mesa disposed on and in direct contact with the rigid support, wherein a proximal end of each of the stamp posts is on and in direct contact with the single mesa.

12. The micro-transfer-printing stamp of claim 9, comprising multiple mesas each in direct contact with the rigid support, wherein a proximal end of more than one of the stamp posts is on and in direct contact with each of the separate mesas.

13. The micro-transfer-printing stamp of claim 9, comprising a separate mesa for each of the stamp posts on and in direct contact with the rigid support, wherein a proximal end of a single stamp post is on and in direct contact with each of the separate mesas.

14. The micro-transfer-printing stamp of claim 1, wherein a line projected through a point or surface of the distal end of the asymmetric distal surface farthest from and orthogonal to the rigid support does not intersect any other portion of the asymmetric distal surface.

15. The micro-transfer-printing stamp of claim 1, wherein a line projected through a point or surface of the distal end of the asymmetric distal surface farthest from and orthogonal to the rigid support intersects another portion of the asymmetric distal surface.

16. The micro-transfer-printing stamp of claim 9, wherein each of the stamp posts in the array is in contact with a neighboring stamp post in one or two dimensions.

17. The micro-transfer-printing stamp of claim 1, wherein the asymmetric distal surface has multiple different surface portions that have different shapes.

18. The micro-transfer-printing stamp of claim 17, wherein at least some different ones of the different shapes are any one or combination of planar and polygonal, nonplanar and curved, nonplanar and convex, or nonplanar and concave.

19. The micro-transfer-printing stamp of claim 17, wherein at least one of the different surface portions is convex and another one of the different surface portions is concave and the convex and the concave surface portions meet at a point or line that is farthest from the rigid support.

20. The micro-transfer-printing stamp of claim 17, wherein (i) the asymmetric distal surface in contact under first pressure with a component has a first contact area; (ii) the asymmetric distal surface in contact under second pressure with a component has a second contact area, and (iii) the first pressure is greater than the second pressure and the first contact area is greater than the second contact area.

21. The micro-transfer-printing stamp of claim 1, wherein the asymmetric distal surface is convex in a direction orthogonal to a surface of the target substrate on or over which the stamp post is disposed.

22. The micro-transfer-printing stamp of claim 1, wherein the asymmetric distal surface is concave in a direction orthogonal to a surface of the target substrate on or over which the stamp post is disposed.

23. The micro-transfer-printing stamp of claim 1, wherein the asymmetric distal surface comprises continuous surface portions having two or more different areas.

24-54. (canceled)
